(19) United States
(12) Patent Application Publication
(10) Pub. No.: US 2008/0038669 A1
(43) Pub. Date: Feb. 14, 2008

(54) NON-TRULY-SPHERICAL HIGH-MOLECULAR FINE PARTICLES, PROCESS FOR PRODUCING THE SAME, INKJET INK COMPOSITION CONTAINING FINE PARTICLES, LITHOGRAPHIC PRINTING PLATE USING THE SAME, PROCESS FOR PRODUCING PRINTING PLATE, AND ELECTROPHORETIC PARTICLES-CONTAINING COMPOSITION CONTAINING FINE PARTICLES

(75) Inventor: Ryuki KAKINO, Haibara-gun (JP)

Correspondence Address: SUGHRUE-265550, 2100 PENNSYLVANIA AVE. NW, WASHINGTON, DC, 20037-3213, US

(73) Assignee: FUJIFILM CORPORATION, Tokyo (JP)

(21) Appl. No.: 11/758,966

(22) Filed: Jun. 6, 2007

(30) Foreign Application Priority Data
Jun. 6, 2006 (JP) 2006-157229

(51) Int. Cl. G03F 7/26; B32B 5/16; G03G 17/04; C08G 63/00

(52) U.S. Cl. 430/302; 428/402; 430/37; 528/271; 528/422; 528/425

(57) ABSTRACT

Non-truly-spherical high-molecular fine particles are produced by a radical polymerization between a first radical-polymerizable monomer having a nucleophilic group and a second radical-polymerizable monomer having a group reacting with the nucleophilic group to form a covalent bond in a non-aqueous solvent in the presence of a dispersion-stabilizing resin.

### BACKGROUND OF THE INVENTION

1. Field of the Invention

The present invention relates to non-truly-spherical high-molecular fine particles, a process for producing them, an inkjet ink composition containing the fine particles, a lithographic printing plate using the composition and a process for producing the printing plate, and an electrophoteric particles-containing composition containing the fine particles.

2. Background Art

High-molecular fine particles are widely used in the fields of organic pigments for paints, organic pigments for coating paper, carriers for diagnostic agents, inkjet ink and electrophoretic particles.

A recording device of recording an image by the system of depositing a liquid ink as small liquid droplets called ink droplets to form recorded dots has been made practicable as an inkjet printer. In comparison with printers of other systems, the inkjet printer has the advantage that it generates less noise and does not require additional processing such as development or fixing and, therefore, has attracted attention as a technique for recording on plain paper. As the inkjet printer system, many systems have so far been devised. In particular, (a) a system wherein ink droplets are made to fly by the pressure of vapor generated by heat of a heating element (e.g., JP-B-56-9429 (the term “JP-B” as used herein means an “examined Japanese patent application”) and JP-B-61-59911) and (b) a system wherein ink droplets are made to fly by mechanical pressure pulses generated by a piezoelectric element (e.g., JP-B-53-12138) are typical systems.

As a recording head for use in the inkjet printer (hereinafter referred to as “inkjet head”), a serial scan type head has been made practicable which is mounted on a carriage and migrates in a direction (hereinafter referred to as “sub scanning direction”) crossing at right angles with a recording paper-conveying direction (hereinafter referred to as “main scanning direction”) to conduct recording. With this serial scan type head, it is difficult to increase the recording speed. Therefore, in order to increase the recording speed, a line-scan type printer has also been devised wherein a long head having the same length as the width of recording paper. However, it is not easy to make such line-scan type head practicable due to the following reasons.

Many individual fine nozzles corresponding to resolution are provided in an inkjet recording device. Local condensation of the ink is liable to take place essentially due to evaporation or volatilization of the solvent, which can be the cause of clogging of the nozzles. Further, in a system wherein vapor pressure is used for forming inkjet, deposition of insoluble substances formed by thermal or chemical reaction with the ink causes clogging of the nozzles and, in a system wherein pressure generated by a piezoelectric element is used, a complicated structure of ink passages or the like further promotes clogging. The line-scan type head using more nozzles than the serial scan type head which uses from several-ten to one-hundred-and-several-ten nozzles, i.e., as many as several thousands of nozzles, has involved the problem that clogging occurs with considerably high frequency in view of probability, thus having no practical reliability.

Further, with the process of using vapor pressure, it is difficult to form ink droplets of 20 μm or less in diameter which correspond to recording dots of several μm in diameter on recording paper, thus a head having high resolution being difficult to produce. Also, with the system wherein pressure generated by a piezoelectric element is used, the head has such a complicated structure that it is difficult to produce a head having high resolution due to problems with processing technique. Thus, with the conventional inkjet recording devices, all of the systems have involved the problem that improvement of resolution is difficult.

In order to solve these problems, there has been proposed an inkjet recording system wherein a voltage is applied to an electrode array on a substrate formed of plural individual electrodes made of thin film to thereby make an ink or a coloring material component therein to fly as ink droplets from the ink liquid surface using the electrostatic force. Specifically, there have been proposed a system wherein ink droplets are made to fly by using electrostatic attractive force (e.g., JP-A-49-62024 (the term “JP-A” as used herein means an “unexamined published Japanese patent application”) and JP-A-56-4467) and a system wherein ink droplets containing a coloring material in a higher concentration are made to fly using an ink containing charged coloring material particles (JP-T-7-502218 (the term “JP-T” as used herein means a published Japanese translation of a PCT patent application)). In these systems, the recording head has a slit-like nozzle structure which does not require nozzles for individual dots or has a nozzle-less structure wherein ink passage walls for ink flow passages for individual dots are not required, and hence they are effective for preventing clogging which is a serious trouble for realizing a line-scan type recording head and effective for restoration after clogging. Also, since the latter system can stably generate ink droplets having an extremely small particle size and can make them to fly, it is adequate for enhancing resolution.

As the polymer particles for use in the electrostatic inkjet system, truly spherical polymer particles obtained by radical polymerization of an acrylic, radical-polymerizable monomer in a non-aqueous solvent as described in JP-A-10-204354 have generally been used.

Also, in recent years, an electrophoretic display device has been proposed wherein colored high-molecular fine particles capable of being electrically charged in an electrophoretic display cell are electrophoresed. For example, JP-A-2001-249366 proposes an electrophoretic display device which can generate display contrast by simple matrix driving and describes black, white or colored particles regarding RGB as colored chageable electrophoretic fine particles to be filled in a cell retaining a transparent organic insulating liquid such as silicone oil, toluene, xylene or highly pure petroleum. Also, as the electrophoretic particles, high-molecular particles of from 0.5 to 20 μm in size such as polyethylene or polystyrene capable of exhibiting chargeable properties in the insulating liquid are disclosed.

Under the above-described circumstances, functional regularly shaped polymer particles of colored resin fine particles colored with a dye or a pigment capable of being charged in an electric field are related to, for example, paper-like display (PLD) wherein charged and colored high-molecular fine particles are electrophoresed in an insulating colorless or colored transparent fluid filled in an electrophoretic display cell. In order to permit the colored high-molecular fine particles to realize the display embodiment as PLD, chargeability and electrophoretic properties of the particles within the display cell having opposed electrodes are extremely important. Therefore, the functional regularly shaped polymer particles to be used in this PLD are colored high-molecular particles exhibiting chargeability of readily responding electrically in an electric field system.

Also, in view of preventing agglomeration of the electrophoretic particles to smoothen the electrophoretic display properties, the particles are desirably particles having a regular shape, preferably a spherical shape, and are desirably mono-disperse particles having less distribution degree (dispersion degree) with respect to the particle size. Further, chargeable functional colored high-molecular fine particles of a static toner are related to electro-photographic image-forming apparatuses such as a copying machine, a laser printer and a facsimile. As such chargeable colored resin fine particles, mono-disperse functional regularly shaped particles with high uniformity in particle size are required which are difficult to agglomerate and form coarse particles upon electrophoresis in the electric field of the former cell and which are difficult to agglomerate in the latter transfer-fixing system.

With chargeable fine particles for use in ink particles for electrostatic inkjet recording or for use as particles for electrophoretic display, it has become a technical subject to enhance response properties to electric field. In order to enhance response properties to electric field, it is necessary to enhance chargeability of the particle surface. The chargeability of the particles greatly depends upon chemical formulation and surface area of the particle surface. With particles having a definite particle size, non-spherical particles have a larger surface area than that of truly spherical particles. However, as chargeable high-molecular fine particles for a non-aqueous system, no examples of non-spherical fine particles have been known.

In recent years, in order to enhance whiteness or luster of paints or enhance function of diagnostic agents, there have been developed polymer particles having a shape different from that of the aforesaid truly spherical dense polymer fine particles. For example, JP-A-2000-38455 discloses flat particles, JP-A-6-287244 discloses particles having many depressions on the surface thereof, JP-A-2002-179708 discloses a process for producing high-molecular fine particles having many surface depressions, JP-A-2003-226708 discloses a process for producing odd-shaped high-molecular fine particles and the odd-shaped fine particulate high polymer, and JP-A-8-259863 discloses an ink for inkjet recording which ink contains non-spherical particles.

However, all of these non-truly-spherical fine particles are synthesized in water or a highly polar solvent and cannot be synthesized in a low-polar non-aqueous solvent. Therefore, they cannot have been used for ink particles or particles for electrophoretic display.

### SUMMARY OF THE INVENTION

The invention has been made with giving attention to the above-mentioned problems, and an object of the invention is to provide non-truly-spherical fine particles having excellent chargeability and, further, to provide an inkjet ink composition having excellent response to electric field by using the fine particles, a lithographic printing plate using the inkjet ink composition and a process for producing the printing plate, and an electrophoretic particles-containing composition using the fine particles.
(1) Non-truly-spherical high-molecular fine particles, which are produced by a radical polymerization between a first radical-polymerizable monomer having a nucleophilic group and a second radical-polymerizable monomer having a group reacting with the nucleophilic group to form a covalent bond in a non-aqueous solvent in the presence of a dispersion-stabilizing resin.
(2) The Non-truly-spherical high-molecular fine particles as described in the item (1), wherein the dispersion-stabilizing resin comprises a polymer soluble in a non-aqueous solvent which polymer has at least a repeating unit represented by the following formula (I): 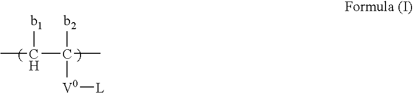
   wherein V⁰ represents one of —COO—, —OCO—, —CH₂COO—, —CH₂OCO— and —O—.
(3) The Non-truly-spherical high-molecular fine particles as described in the item (1), wherein the first radical-polymerizable monomer has a substituent group selected from the group consisting of a radical-polymerizable monomer having a carboxyl group, a primary amino group, a secondary amino group, a phenoxy group, an alkoxy group, a hydroxyl group, a thiol group, a thioalkoxy group, a thiophenoxy group, a —COCHCO— group, a —COCHSO₂— group, a —CONHSO₂— group and a —SO₂NHSO₂— group.
(4) The Non-truly-spherical high-molecular fine particles as described in the item (1), wherein the second radical-polymerizable monomer has a substituent group selected from the group consisting of an epoxy group, an isocyanato group, a thioisocyanato group, an oxetane group, a fluoroalkyl group, a chloroalkyl group, a bromoalkyl group, an iodoalkyl group, a sulfonic acid group, a trifluoromethanesulfonic acid alkyl group, a perfluoroalkanesulfonic acid alkyl group such as pentafluoroethanesulfonic acid alkyl group, tosylic acid alkyl group and a perfluoroalkanecarboxylic acid alkyl group.
(5) The Non-truly-spherical high-molecular fine particles as described in the item (1), wherein the first and second radical-polymerizable monomers comprise a cationic monomer having a cationic group selected from the group consisting of at least one amino group represented by the general formula (II) within the molecule and polymerizable monomers having a nitrogen-containing hetero ring. 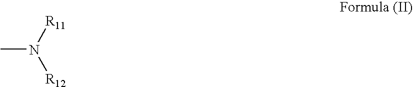
   wherein R₁₁ and R₁₂, which is the same or different, each represents one of a hydrogen atom and a hydrocarbon group containing from 1 to 22 carbon atoms. R₁₁ and R₁₂ are connected to each other to form a ring.
(6) The Non-truly-spherical high-molecular fine particles as described in the item (5), wherein the cationic monomer is mixed with the first and second radical-polymerizable monomers in a proportion of from 1 to 50% by weight based on the total weight of the first and second radical-polymerizable monomers and the cationic monomer.
(7) The Non-truly-spherical high-molecular fine particles as described in the item (1), which have a molar ratio of the first radical-polymerizable monomer to the second radical-polymerizable monomer being from 9:1 to 1:9.
(8) The Non-truly-spherical high-molecular fine particles as described in the item (1), which have an average particle size being from 0.05 to 10 μm.
(9) The Non-truly-spherical high-molecular fine particles as described in the item (1), wherein the dispersion-stabilizing resin has an amount being from 3 to 40 parts by weight per 100 parts by weight of total monomers.
(10) A process for producing non-truly-spherical high-molecular fine particles, which comprise: dissolving, in a non-aqueous solvent, a dispersion-stabilizing resin, a first radical-polymerizable monomer having a nucleophilic group and a second radical-polymerizable monomer having a group capable of reacting with the nucleophilic group to form a covalent bond so as to form resin particles; adding thereto a radical polymerization initiator; and heating the mixture to conduct radical polymerization reaction.
(11) The process for producing non-truly-spherical high-molecular fine particles as described in the item (10), wherein the non-truly-spherical high-molecular fine particles has a weight ratio of the resin particles to total weight of the first and second radical-polymerizable monomers is from 5:95 to 95:5.
(12) An inkjet ink composition, which comprises the non-truly-spherical high-molecular fine particles as described in the item (1).
(13) A process for producing a lithographic printing plate, which comprises: ejecting the inkjet ink as described in the item (13) to deposit onto a hydrophilic support; and curing the deposited inkjet ink composition by irradiation with radiation to form a hydrophobic region.
(14) A lithographic printing plate, which is produced by the process for producing a lithographic printing plate as described in the item (13).
(15) An electrophoretic particles-containing composition, which comprises: non-truly-spherical high-molecular fine particles as described in the item (1); a non-aqueous solvent; and a charge-adjusting agent.

In comparison with particles having the same average particle size, the non-truly-spherical high-molecular fine particles of the invention have a larger particle surface area, and hence they have a more amount of charge thereon and, in addition, since contact area with other substance is smaller, they have better particle re-dispersibility and better washability to remove deposited particles.

The non-truly-spherical high-molecular fine particles of the invention provide an inkjet ink composition which has excellent response to electric field and which ensures stable ejection for a long period of time. They also provide an inkjet ink composition having excellent re-dispersibility.

Also, the non-truly-spherical high-molecular fine particles of the invention provide an electrophoretic particles-containing composition having excellent electrophoretic properties.

The non-truly-spherical high-molecular fine particles can find application to various uses such as an electrostatic inkjet ink, an ink composition for a printing plate obtained by inkjet type plate-making, an electrophoretic display, electrophoretic electronic paper and a toner for developing an electrostatic charge image.

### BRIEF DESCRIPTION OF THE DRAWINGS

The invention disclosed herein will be understood better with reference to the following drawings of which:

FIG. 1 is a drawing showing the constitution of an inkjet recording device adequate for using the ink composition of the invention.

FIG. 2 is a drawing showing a structural unit of an electrophoretic display device.

FIG. 3 is a schematic drawing of an electrophoretic display device.

FIG. 4 shows an image of a fine particle 1 of the resin synthesized in Example 1, photographed by means of an electron microscope.

### DETAILED DESCRIPTION OF THE INVENTION

The invention will be described in detail below.

(Non-Truly-Spherical High-Molecular Fine Particles)

The high-molecular fine particles of the invention useful for an inkjet ink composition or an electrophoretic particles-containing composition and excellent in chargeability are characterized in that they are non-truly-spherical.

As a measure for being non-truly-spherical, average circularity of the particles can be determined by observing the shape of particles with an electron microscope and conducting analysis of the image.

The non-truly-spherical high-molecular fine particles having excellent chargeability are non-truly-spherical high-molecular fine particles having an average circularity of 0.95 or less.

The average circularity of high-molecular fine particles can easily be determined by obtaining an image of particles by means of a flow type particle image analyzer FPIA-2100 manufactured by SYSMEX CORPORATION and analyzing the image. The non-truly-spherical high-molecular fine particles of the invention have an average circularity of 0.95 or less, preferably from 0.95 to 0.5.

The average circularity can also be determined by image processing of an SEM image.

The circularity is defined as a value obtained by dividing the peripheral length of a circle having the same projected area of a particle image by the peripheral length of a projected image of the particle, and the average circularity (Ca) is a value determined according to the following formula (I).

$$Average circularity ( Ca ) = ( {\sum }_{i = 1}^{n} ( Ci \times fi ) ) / {\sum }_{i = 1}^{n} ( fi ) \qquad Formula ( I )$$

In the above formula, n is a population of particles whose circularity Ci has been determined. In the above formula, Ci is a circularity of each particle calculated according to the following formula based on the peripheral length measured with respect to each particle of a group of particles having an equivalent circle diameter of from 0.6 to 400 μm.
Circularity (Ci)=(peripheral length of a circle having the same area as the projected area of a particle)/(peripheral length of projected image of the particle)

In the above formula, fi is a frequency of particles having a circularity of Ci.

The average circularity is used as a simple means for quantitatively representing the shape of particles, and is an index showing the degree of unevenness of the particles. Completely spherical fine particles have an average circularity of 1, and the average circularity becomes smaller as the surface profile of the fine particles becomes more complicated.

In the invention, it has been found that non-truly-spherical high-molecular fine particles having an average circularity of 0.95 or less can be obtained by radical polymerization of a radical-polymerizable monomer in a non-aqueous solvent in the presence of a dispersion-stabilizing resin.

A process for synthesizing non-truly-spherical high-molecular fine particles having an average circularity of 0.95 or less will be described below.

(Non-Aqueous Solvent)

The non-aqueous solvent is preferably a non-polar insulating solvent having a specific inductive capacity of from 1.5 to 20 and a surface tension of from 15 to 60 mN/m (at 25° C.), and those which have low toxicity, small flammability and little offensive smell are preferred. Examples of such non-aqueous solvent include those solvents which are selected from among straight-chain or branched-chain aliphatic hydrocarbons, alicyclic hydrocarbons, aromatic hydrocarbons, petroleum naphtha and halogen-substituted products thereof. For example, solvents selected from among hexane, octane, isooctane, decane, isodecane, decalin, nonane, dodecane, isododecane, Isopar E, Isopar G, Isopar H and Isopar L of Exxon Corporation, Solutol of Phillip Corporation, IP Solvent of Idemitsu Kosan Co., Ltd. and, as petroleum naphtha, S.B.R., Shelzol 70 and Shelzol 71 of Shell Petrochemical Corporation and Begazol of Mobil Petroleum Corporation can be used independently or as a mixture thereof.

As preferred hydrocarbon solvents, high purity isoparaffin series hydrocarbons having a boiling point in the range of from 150 to 350° C. are illustrated. As commercially available products, the aforementioned Isopar G, H. L, M and V (trade names) and Noper 12, 13 and 15 (trade names) manufactured by Exxon Chemical Corporation, IP Solvent 1620 and 2028 (trade names) manufactured by Idemitsu Kosan Co., Ltd., Isozol 300 and 400 (trade names) manufactured by Japan Petrochemical Co. Ltd., and Amusco OMS and Amusco 460 solvents (Amusco; trade names of Spirits Corporation) are illustrated. These products are aliphatic saturated hydrocarbons with extremely high purity, and are 3 cSt or less in viscosity at 25° C., 22.5 to 28.0 mN/m in surface tension at 25° C., and 10¹⁰ Ω·cm or more in specific resistance at 25° C. Also, they have features of being stable with low reactivity and highly safe with low toxicity and giving little offensive smell.

As halogen-substituted hydrocarbon series solvents, there are fluorocarbon solvents including perfluoroalkanes represented by CₙF₂ₙ₊₂, for example, C₇F₁₆ and C₈F₁₈ (Florinat PF5080 and Florinat PF5070 (trade names) manufactured by Sumitomo 3M Corporation, and the like), fluorine-containing inert liquids (Florinat FC series (trade name) manufactured by Sumitomo 3M Corporation, and the like), fluorocarbons (Crytocks GPL series (trade name) manufactured by Du Pont Japan Limited Co., Ltd., and the like), flons (HCFC-141b (trade name) manufactured by Daikin Kogyo Industries, Ltd., and the like) and iodinated fluorocarbons such as [F(CF₂)₄CH₂CH₂I] and [F(CF₂)₆I] (I-1420 and I-1600 (trade names) manufactured by Daikin Fine Chemical Laboratory, and the like).

As the non-aqueous solvents to be used in the invention, higher fatty acid esters and silicone oils can further be used as well. Specific examples of the silicone oils include low viscosity synthetic dimethylpolysiloxanes. As commercially available products, KF961 (trade name) manufactured by Shin-Etsu Silicone Co., Ltd. and SH200 (trade name) manufactured by Toray Dow Corning Silicone Co., Ltd. are illustrated.

Silicone oils are not limited to these specific examples. As these dimethylpolysiloxanes, products with a very wide range of viscosity are available depending upon their molecular weights, but it is preferred to use those with a viscosity of from 1 to 20 cSt. These dimethylpolysiloxanes have a volume resistivity of 10¹⁰ Ω·cm or more similarly to isoparaffin series hydrocarbons and have features of being highly stable and highly safe and giving no offensive smell. Further, these dimethylpolysiloxanes are characterized by low surface tension and have a surface tension of from 18 to 21 mN/m.

As solvents capable of being mixed with these organic solvents to use, there are illustrated alcohols (e.g., methyl alcohol, ethyl alcohol, propyl alcohol, butyl alcohol and fluorinated alcohol), ketones (e.g., methyl ethyl ketone and cyclohexanone), carboxylates (e.g., methyl acetate, ethyl acetate, propyl acetate, butyl acetate, methyl propionate and ethyl propionate), ethers (e.g., diethyl ether, dipropyl ether, tetrahydrofuran and dioxane) and halogenated hydrocarbons (e.g., methylene dichloride, chloroform, carbon tetrachloride, dichloroethane and methylchloroform).

(Dispersion-Stabilizing Resin (P))

The dispersion-stabilizing resin (P) to be used in the invention is used for preparing a stable dispersion of non-truly-spherical high-molecular particles (CR) produced by polymerizing a radical-polymerizable monomer in a non-aqueous solvent. The dispersion-stabilizing resin (P) is preferably a polymer soluble in a non-aqueous solvent which polymer has at least a repeating unit represented by the following general formula (II). The moiety represented by the general formula (II) is a moiety which is soluble in the non-aqueous solvent.

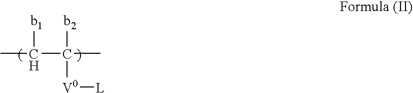

In the general formula (II), V⁰ represents preferably —COO—, —OCO—, —CH₂COO—, —CH₂OCO— or —O—, more preferably —COO—, —OCO— or —CH₂COO—.

L preferably represents an optionally substituted alkyl or alkenyl group containing from 8 to 32 carbon atoms. Examples of the substituents include a halogen atom (e.g., a fluorine atom, a chlorine atom or a bromine atom), —O-D², —COO-D² and —OCO-D² (wherein D² represents an alkyl group containing from 6 to 22 carbon atoms; e.g., a hexyl group, an octyl group, a decyl group, a dodecyl group, a hexadecyl group or an octadecyl group). More preferably, L represents an alkyl or alkenyl group containing from 10 to 22 carbon atoms. Examples thereof include a decyl group, a dodecyl group, a tridecyl group, a tetradecyl group, a hexadecyl group, an octadecyl group, a docosyl group, an eicosyl group, a decenyl group, a dodecenyl group, a tridecenyl group, a tetradecenyl group, a pentadecenyl group, a hexadecenyl group, a heptadecenyl group, an octadecenyl group and a docosenyl group.

b¹ and b², which may be the same or different, each preferably represents a hydrogen atom, a halogen atom (e.g., a fluorine atom, a chlorine atom or a bromine atom), a cyano group, an alkyl group containing from 1 to 3 carbon atoms, —COO-D³ or —CH₂COO-D³ (wherein D³ represents an aliphatic group containing from 1 to 22 carbon atoms such as a methyl group, an ethyl group, a propyl group, a butyl group, a hexyl group, an octyl group, a decyl group, a dodecyl group, a tridecyl group, a tetradecyl group, a hexadecyl group, an octadecyl group, a docosyl group, a pentenyl group, an hexenyl group, a heptenyl group, an octenyl group, a decenyl group, a dodecenyl group, a tetradecenyl group, a hexadecenyl group or an octadecenyl group; these aliphatic groups optionally having a substituent similar to that referred to with respect to L). More preferably, b¹ and b² each represents an alkyl group containing from 1 to 3 carbon atoms (e.g., a methyl group, an ethyl group or a propyl group), —COO-D⁴or —CH₂COO-D⁴ (wherein D⁴ represents an alkyl or alkenyl group containing from 1 to 12 carbon atoms such as a methyl group, an ethyl group, a propyl group, a butyl group, a hexyl group, an octyl group, a decyl group, a dodecyl group, a pentenyl group, an hexenyl group, a heptenyl group, an octenyl group or a decenyl group; these alkyl and alkenyl groups optionally having a substituent similar to that referred to with respect to L).

The dispersion-stabilizing resin (P) is preferably a copolymer obtained by copolymerizing a monomer corresponding to the repeating unit represented by the above general formula (II) with other monomer copolymerizable with the former monomer.

The other copolymerizable monomer may be any monomer that has a polymerizable double bond, and examples thereof include unsaturated carboxylic acids such as acrylic acid, methacrylic acid, crotonic acid and itaconic acid; ester derivatives or amide derivatives of unsaturated carboxylic acids containing 6 or less carbon atoms; vinyl esters or allyl esters of carboxylic acids; styrenes; methacrylonitrile; acrylonitrile; and hetero ring compounds containing a polymerizable double bond.

More specific examples thereof include vinyl esters or allyl esters of aliphatic carboxylic acids containing from 1 to 6 carbon atoms (e.g., acetic acid, propionic acid, butyric acid and monochloroacetic acid); optionally substituted alkyl esters or amides containing from 1 to 4 carbon atoms of unsaturated acids such as acrylic acid, methacrylic acid, crotonic acid, itaconic acid and maleic acid (examples of the alkyl group being a methyl group, an ethyl group, a propyl group, a butyl group, a 2-chloroethyl group, a 2-bromoethyl group, a 2-hydroxyethyl group, a 2-cyanoethyl group, a 2-nitroethyl group, a 2-methoxyethyl group, a 2-methanesulfonylethyl group, a 2-benzenesulfonylethyl group, a 2-carboxyethyl group, a 4-carboxybutyl group, a 3-chloropropyl group, a 2-hydroxy-3-chloropropyl group, a 2-furfurylethyl group, a 2-thienylethyl group and a 2-carboxamidoethyl group); styrene derivatives (e.g., styrene, vinyltoluene, α-methylstyrene, vinylnaphthalene, chlorostyrene, dichlorostyrene, bromostyrene, vinylbenzenecarboxylic acid, chloromethylstyrene, hydroxymethylstyrene, methoxymethylstyrene, vinylbenzenecarboxamide and vinylbenzenesulfamide); unsaturated acids such as acrylic acid, methacrylic acid, crotonic acid, maleic acid and itaconic acid; cyclic acid anhydrides of maleic acid and itaconic acid; acrylonitrile; methacrylonitrile; and hetero ring compounds having a polymerizable double bond (specifically those compounds which are described in, for example, Kobunshi Data Handbook—Kisohen—(High Polymer Data Handbook—Basic Course—) compiled by Kobunshi Gakkai, pp. 175-184, Baifukan (published in year 1986) and are exemplified by N-vinylpyridine, N-vinylimidazole, N-vinylpyrrolidone, vinylthiophene, vinyltetrahydrofuran, vinyloxazoline, vinylthiazole and N-vinylmorpholine). These other monomers may be used in combination of two or more thereof.

The content of the component of the repeating unit represented by the general formula (II) in the dispersion-stabilizing resin (P) is at least 50% by weight or more, preferably 60% by weight or more, more preferably 70% by weight or more, based on the all components of the polymer. Also, regarding the dispersion-stabilizing resin (P), polymerization of the copolymerization component represented by the general formula (II) and soluble in a non-aqueous solvent and the other monomer copolymerizable with the former monomer may be either of random copolymerization and block copolymerization, with block copolymerization being preferred. Additionally, the dispersion-stabilizing resin (P) in the invention does not have any cross-linked structure between the polymer main chains.

In a further preferred embodiment of the dispersion-stabilizing resin (P) of the invention, a polymerizable double bond group represented by the following general formula (III) is bound to the one end of the polymer main chain or in a substituent of a repeating component constituting the polymer (such resin being also referred to as dispersion-stabilizing resin (PG)). This polymerizable double bond group may be any functional group copolymerizable with a radical-polymerizable monomer to be described hereinafter which constitutes the non-truly-spherical high-molecular fine particles.

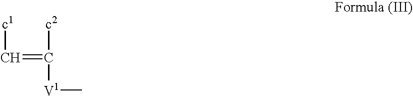

In the general formula (III), V¹ represents —COO—, —OCO—, —(CH₂)ₜCOO—, —(CH₂)ₜOCO—, —O—, —SO₂—, —CONHCOO—, —CONHCONH—, —CON(D²)-, —SON(D²) (wherein D² represents a hydrogen atom or a hydrocarbon group such as an alkyl group containing from 1 to 22 carbon atoms, and t represents an integer of from 1 to 4) or 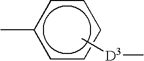
(wherein D³represents a single bond, —O—, —OCO— or —COO—).

c¹ and c², which may be the same or different, are the same as b¹ and b² defined with respect to the general formula (II). It is more preferred that either of c¹ and c² represents a hydrogen atom.

Also, in V¹, D² in the linking group of —CON(D²)- and —SO₂N(D²)- preferably represents a hydrogen atom or an alkyl group such as a methyl group, an ethyl group, a propyl group, a butyl group, a pentyl group, a hexyl group, a heptyl group, an octyl group, a decyl group or a dodecyl group.

As an embodiment of the resin (PG) wherein a polymerizable double bond group is bound to one end of the polymer main chain, there is illustrated, for example, a resin represented by the following general formula (Pa).

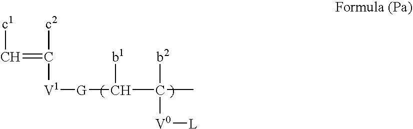

In the general formula (Pa), symbols other than G are the same as defined with respect to corresponding symbols in the formulae (II) and (III). G represents a bond directly connecting to one end of the polymer main chain or a binding group via any linking group.

The binding group is constituted by any combination of atoms such as carbon atom-carbon atom bond (single bond or double bond), carbon atom-hetero atom bond (examples of hetero atom including oxygen atom, sulfur atom, nitrogen atom and silicon atom) and hetero atom-hetero atom bond. For example, there are illustrated 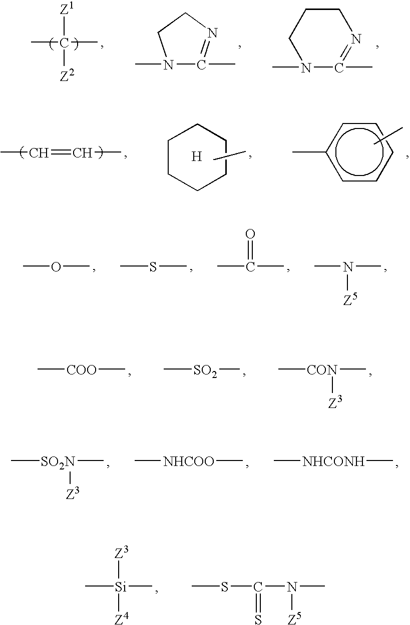
wherein z¹ and z² each represents a hydrogen atom, a halogen atom (e.g., a fluorine atom, a chlorine atom or a bromine atom), a cyano group, a hydroxyl group or an alkyl group (e.g., a methyl group, an ethyl group or a propyl group), and z³ and z⁴ each represents a hydrogen atom, a hydrocarbon group containing from 1 to 8 carbon atoms (e.g., a methyl group, an ethyl group, a propyl group, a butyl group, a pentyl group, a hexyl group, a benzyl group, a phenethyl group, a phenyl group or a tolyl group) or -Oz⁵ (wherein z⁵ is the same as the hydrocarbon group referred to with respect to z³).

The polymerizable double bond group represented by the general formula (III) which is bound to one end of the polymer main chain as mentioned above will be specifically shown below. In the following specific examples, however, A represents —H, —CH₃ or —CH₂COOCH₃, B represents —H or —CH₃, n represents an integer of from 2 to 10, m represents 2 or 3, t represents 1, 2 or 3, p represents an integer of from 1 to 4, and q represents 1 or 2.

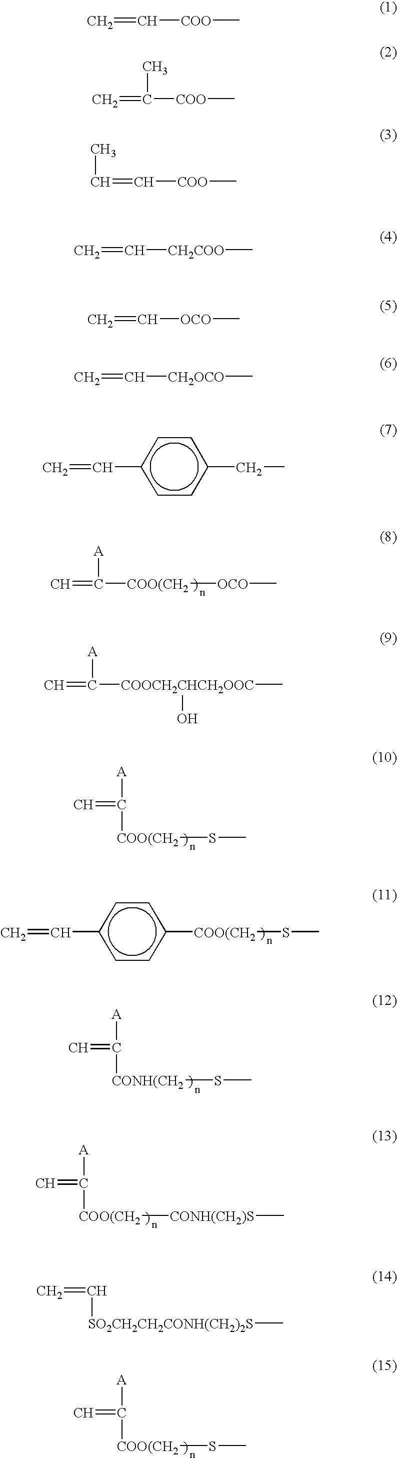

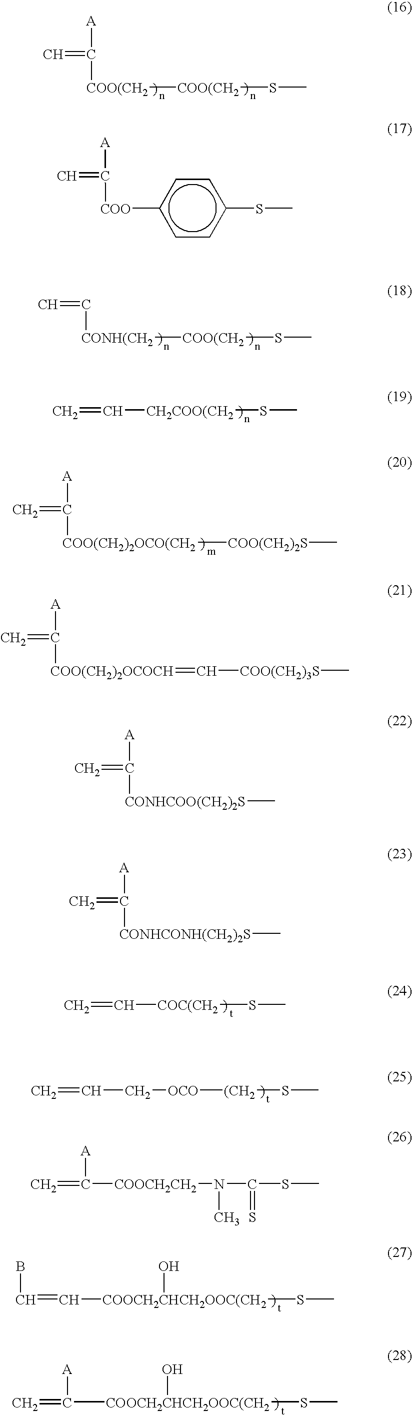

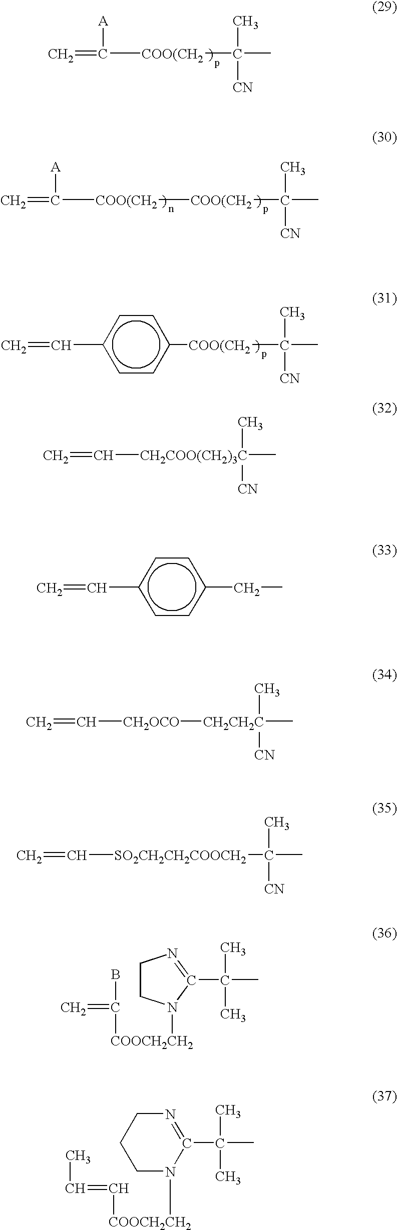

The dispersion-stabilizing resin (PG) of the invention wherein the polymerizable double bond group is bound to one end of the polymer main chain can easily be produced by reacting a reagent containing a varying double bond group with one end of a living polymer obtained by conventionally known radical polymerization (e.g., iniferter method), anion polymerization or cation polymerization, or by a synthesis process such as a process of reacting a reagent containing a particular reactive group (e.g., —OH, —COOH, —SO₃H, —NH₂, —SH, —PO₃H₂, —NCO, —NCS, 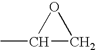
—COCl or —SO₂Cl) with one end of this living polymer and then introducing a polymerizable double bond group by polymer reaction (process according to ion polymerization process) or a process of conducting radical polymerization using a polymerization initiator and/or a chain transfer agent containing the above-mentioned particular reactive group within the molecule and then conducting polymer reaction utilizing the particular reactive group bound to one end of the polymer main chain to thereby introduce a polymerizable double bond group.

Specifically, the polymerizable double bond group can be introduced according to processes described in reviews such as Takayuki Otsu, Kobunshi, 33 (No. 3), 222 81984); P. Dreyfuss & R. P. Quirk, Encycl. Polym. Sci. Eng., 7, 551 (1987); Yoshiki Nakajo & Yuya Yamashita, Senryo To Yakuhin, 30, 232 (1985); Akira Ueda & Susumu Nagai, Kagaku To Kogyo, 60, 57 (1986); P. F. Rempp & E. Franta, Advances in Polymer Science, 58, 1 (1984); Koichi Ito, Kobunshi Kako, 35, 262 (1986); and V. Percec, Applied Polymer Science, 285, 97 (1984) and literatures cited therein.

More specifically, there is illustrated a process of synthesizing a polymer wherein the particular reactive group is bound to one end of the polymer main chain by, for example, (a) a process of polymerizing a mixture of at least one monomer corresponding to the repeating unit represented by the general formula (II) and a chain transfer agent having the above-mentioned particular reactive group within the molecule with the aid of a polymerization initiator (e.g., an azobis compound or a peroxide), (b) a process of polymerizing by using a polymerization initiator containing the above-mentioned particular reactive group within the molecule without using the chain transfer agent or (c) a process of using a chain transfer agent and a polymerization initiator both having the above-mentioned particular reactive group within the molecules, and then introducing a polymerizable double bond group by polymer reaction.

As the chain transfer agent to be used, there are illustrated, for example, mercapto compounds containing a particular reactive group or a substituent capable of being converted to the particular reactive group {e.g., thioglycollic acid, thiomalic acid, thiosalicylic acid, 2-mercaptopropionic acid, 3-mercaptopropionic acid, 3-mercaptobutyric acid, N-(2-mercaptopropionyl)glycine, 2-mercaptonicotinic acid, 3-[N-(2-mercaptoethyl)carbamoyl]propionic acid, 3-[N-(2-mercaptoethyl)amino]propionic acid, N-(3-mercaptopropionyl)alanine, 2-mercaptoethanesulfonic acid, 3-mercaptopropanesulfonic acid, 4-mercaptobutanesulfonic acid, 2-mercaptoethanol, 1-mercapto-2-propanol, 3-mercapto-2-butanol, mercaptophenol, 2-mercaptoethylamine, 2-mercaptoimidazole and 2-mercapto-3-pyridinol} and iodinated alkyl compounds containing a particular reactive group or a substituent capable of being converted to the particular reactive group (e.g., iodoacetic acid, iodopropionic acid, 2-iodoethanol, 2-iodoethanesulfonic acid and 3-iodopropanesulfonic acid). Mercapto compounds are preferred.

As the polymerization initiator containing a particular reactive group or a substitutent capable of being converted to the particular reactive group, there are illustrated, for example, azobis compounds {e.g., 4,4′-azobis(4-cyanovaleric acid), 4,4′-azobis(4-cyanovaleric acid chloride), 2,2′-azobis(2-cyanopropanol), 2,2′-azobis(2-cyanopentanol), 2,2′-azobis[2-(5-hydroxy-3,4,5,6-tetrahydropyrimidin-2-yl)propane], 2,2′-azobis{2-methyl-N-[1,1-bis(hydroxymethyl)-2-hydroxyethyl]propioamide}, 2,2′-azobis{2-methyl-N-[1,1-bis(hydroxymethyl)ethyl]propioamide}, 2,2′-azobis[2-methyl-N-(2-hydroxyethyl)-propioamide] and 2,2′-azobis(2-amidinopropane)} and thiocarbamate compounds {e.g., benzyl N-methyl-N-hydroxyethyldithiocarbamate, 2-carboxyethyl N,N-diethyldithiocarbamate and 3-hydroxypropyl N,N-dimethyldithiocarbamate}.

The amount of each of the chain transfer agents or the polymerization initiators to be used is from 0.05 to 10 parts by weight, preferably from 0.1 to 5 parts by weight, per 100 parts by weight of all monomers.

As a specific embodiment of the resin (PG) containing a polymerizable double bond group in a substituent of the polymerization component of the polymer, there are illustrated those which are represented by the following general formula (Pb).

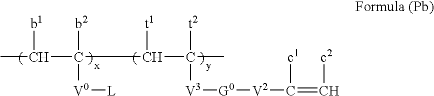

In formula (Pb), b¹, b², V^{o}, L, c¹ and c² are the same as has been defined above. Two or more kinds of component x and component y may be contained in the resin (P). t¹ and t² are the same as aforementioned b¹ and b², respectively. V² and V³ are the same as V¹ defined with respect to formula (III). G⁰ represents a group which links the binding group V² and the binding group V³ and comprises at least one carbon atom, oxygen atom, sulfur atom, silicon atom or nitrogen atom.

The binding group is constituted by any combination of atoms such as carbon atom-carbon atom bond (single bond or double bond), carbon atom-hetero atom bond (examples of hetero atom including oxygen atom, sulfur atom, nitrogen atom and silicon atom) and hetero atom-hetero atom bond and hetero ring groups. For example, as the atoms, there are illustrated 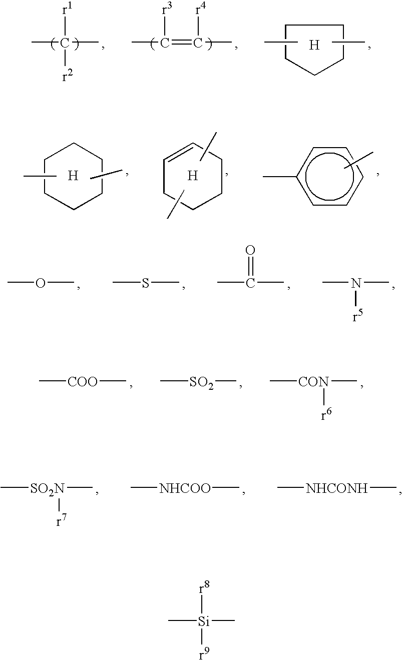
wherein r¹ to r⁴ each represents a hydrogen atom, a halogen atom (e.g., a fluorine atom, a chlorine atom or a bromine atom), a cyano group, a hydroxyl group, an alkyl group (e.g., a methyl group, an ethyl group or a propyl group) or the like, r⁵ to r⁷ each represents a hydrogen atom or an alkyl group (e.g., a methyl group, an ethyl group, a propyl group or a butyl group), and r⁸ and r⁹ each represents a hydrogen atom, a hydrocarbon group containing from 1 to 8 carbon atoms (e.g., a methyl group, an ethyl group, a propyl group, a butyl group, a pentyl group, a hexyl group, a benzyl group, a phenethyl group or a tolyl group) or -Or¹⁰ (wherein r¹⁰ is the same as the hydrocarbon group defined with respect to r⁸).

Also, as the hetero ring group, hetero rings containing a hetero atom such as an oxygen atom, a sulfur atom or a nitrogen atom (e.g., a thiophene ring, a pyridine ring, a pyran ring, an imidazole ring, a benzimidazole ring, a furan ring, a piperidine ring, a pyrazine ring, a pyrrole ring and a piperazine ring) are illustrated.

In the component y in the general formula (Pb), the sum total of the number of atoms in the linking main chain constituted by the binding group [—V³-G⁰-V²—] is preferably 8 or more. Here, regarding the number of atoms in the linking main chain, in the case where V³ represents —COO— or —CONH—, the oxo group (═O group) and the hydrogen atom are not counted as the atoms constituting the linking main chain, whereas the carbon atoms, the ether type oxygen atom and the nitrogen atom constituting the linking main chain are counted. Thus, with —COO— and —CONH—, the number of atoms is counted as 2.

Specific examples of the repeating unit (component y) containing a polymerizable double bond group are shown below which, however, do not limit the invention in any way. In the following formulae, each sign represents the following content.

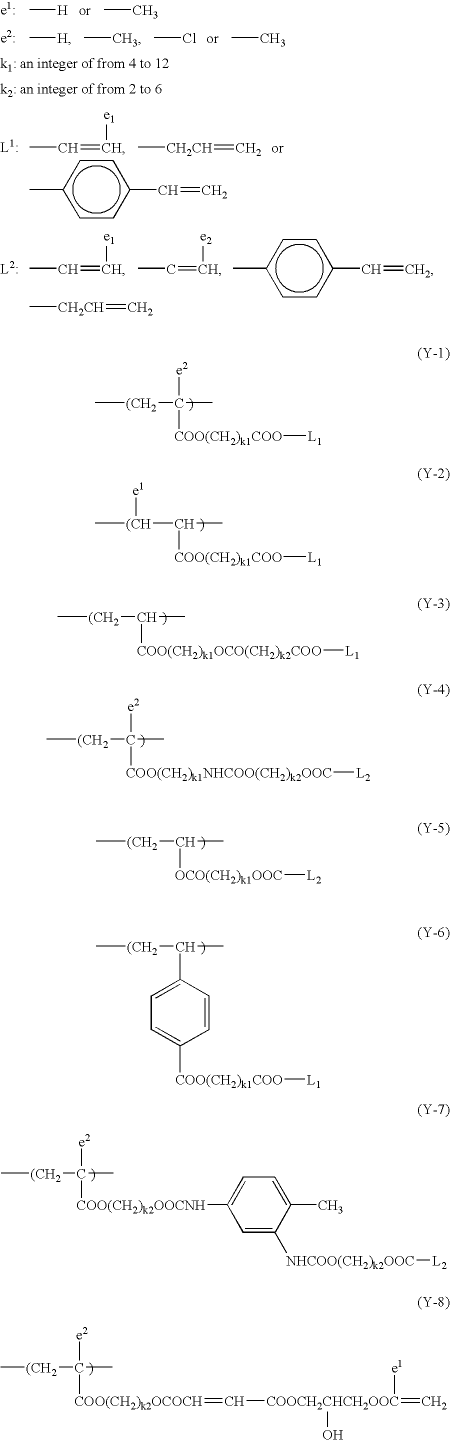

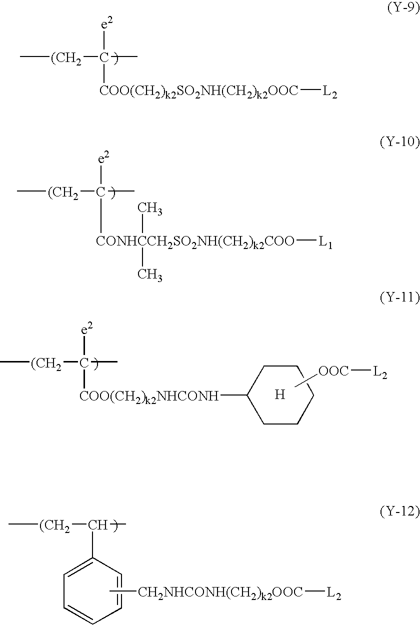

The dispersion-stabilizing resin (PG) containing the polymerizable double bond group in the substituent of the polymerization component can be easily synthesized according to conventionally known synthetic processes. That is, as a process for introducing a polymerization component (component y) containing a polymerizable double bond group into the resin, there is illustrated a process of subjecting a monomer previously containing a particular reactive group (e.g., —OH, —COOH, —SO₃H, —NH₂, —SH, —PO₃H₂, —NCO, —NCS, —COCl, —SO₂Cl or an epoxy group) to polymerization reaction together with a monomer corresponding to the component x in the general formula (Pb), and then reacting with a reactive reagent containing a polymerizable double bond group to thereby introduce the polymerizable double bond group by polymer reaction.

Specifically, the polymerizable double bond group can be introduced into one end of the polymer main chain according to processes described in the reviews having been illustrated with respect to the polymerizable double bond-containing resin (PG) and literatures cited therein.

As other process, there is illustrated a process described in JP-A-60-185962 which comprises reacting a bifunctional monomer different in polymerization reactivity in radical polymerization reaction with a monomer corresponding to the component x to synthesize a copolymer represented by the general formula (Pb) without causing gelation reaction.

In the resin represented by the general formula (Pb), the existing ratio of component x/component y is from 90/10 to 99/1, preferably from 92/8 to 98/2. When the ratio is within this range, there exists no possibility of gelation of the reaction mixture or formation of coarse resin particles with a large diameter upon polymerization reaction to form the particles.

Further, the dispersion-stabilizing resin (PG) to be subjected to the invention may contain other repeating units as copolymerication components in addition to the repeating units of the general formulae (Pa) and (Pb). As the other copolymerization components, any compound may be employed that comprises a monomer copolymerizable with a monomer corresponding to each of the repeating units of the general formulae (Pa) and (Pb). However, in order to obtain dispersed resin particles with good dispersion stability, the other copolymerization components are used in an amount of preferably at most not exceeding 20 parts by weight in 100 parts by weight of the all polymerizable components.

One preferred embodiment of the dispersion-stabilizing resin (P) of the invention is a graft polymer (hereinafter in some cases also referred to as dispersion-stabilizing resin (PF)) containing at least one monomer which constitutes the main chain moiety soluble in a non-aqueous dispersing medium and at least one macromonomer which constitutes the graft moiety (side chain moiety) insoluble in the non-aqueous dispersing medium.

In the invention, the graft polymer is a polymer comprising a main chain having a graft chain as a side chain, and is not particularly limited as long as it is soluble in a solvent. Preferably, the graft polymer is a polymer of 1,000 or more in weight-average molecular weight containing a graft chain of a polymer component of 500 or more in weight-average molecular weight as a side chain. A graft polymer particularly preferred as the dispersing agent is a polymer whose main chain moiety is not soluble in the dispersing medium and whose side chain moiety (graft chain) is soluble in the dispersing medium.

The term “main chain moiety is not soluble in the dispersing medium” as used herein means that a polymer constituted by the main chain moiety alone not having any side chain is not soluble in the dispersing medium and, specifically, has a solubility (25° C.) of preferably 3 g or less for 100 g of the dispersing medium.

The term “side chain moiety is soluble in the dispersing medium” as used herein means that a polymer constituted by the side chain moiety alone not having the main chain moiety is soluble in the dispersing medium and, specifically, has a solubility (25° C.) of preferably 5 g or more for 100 g of the dispersing medium.

In the dispersing medium, the graft polymer whose main chain moiety is not dissolved and whose side chain moiety is dissolved is in a transparent to white-turbid state, thus being dissolved or dispersed therein. In the case when such graft polymer is used, the main chain moiety strongly adsorbs on the particles, whereas the side chain moiety is dissolved in the dispersing medium, thereby affinity of the side chain moiety for the dispersing medium being improved. As a result, dispersiblity of the particles in the dispersing medium is improved.

Graft polymers to be preferably used in the invention are polymers of 1,000 or more in weight-average molecular weight containing at least a constituting unit represented by the following general formula (IV) and a constituting unit represented by the following general formula (V).

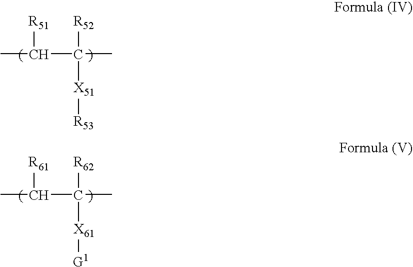

In the general formulae (IV) and (V), R₅₁, R₅₂, R₆₁ and R₆₂, which may be the same or different, each represents a hydrogen atom or a methyl group.

R₅₃ represents a hydrogen atom or a hydrocarbon group containing from 1 to 30 carbon atoms and optionally having a substituent. The hydrocarbon group of R₅₃ may contain an ether bond, an ester bond, an amide bond, a carbamate bond, an amino group, a hydroxyl group or a halogen substituent.

X₅₁ and X₆₁, which may be the same or different, each represents a single bond or a divalent linking group comprising two kinds or more atoms selected from among C, H, N, O, S and P with the sum total number of the atoms being 50 or less.

G¹ represents a polymer component of 500 or more in weight-average molecular weight containing at least a constituting unit represented by the following general formula (VI) or represents a polydimethylsiloxane group of 500 or more in weight-average molecular weight.

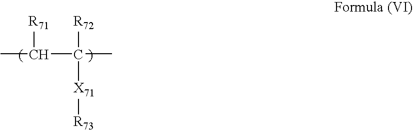

In the general formula (VI), R₇₁ and R₇₂, which may be the same or different, each represents a hydrogen atom or a methyl group.

R₇₃ represents a hydrogen atom or a hydrocarbon group containing from 1 to 30 carbon atoms and optionally having a substituent. The hydrocarbon group of R₇₃ may contain an ether bond, an ester bond, an amide bond, a carbamate bond, an amino group, a hydroxyl group or a halogen substituent.

X₇₁ represents a single bond or a divalent linking group comprising two kinds or more atoms selected from among C, H, N, O, S and P with the sum total number of the atoms being 50 or less.

Additionally, in view of dispersion stability, the sum total number of atoms of R₇₃ is preferably more than the sum total number of atoms of R₅₃.

The graft polymer to be preferably used in the invention which contains at least the constituting unit represented by the general formula (IV) and the constituting unit represented by the general formula (V) can be obtained by polymerizing a radical-polymerizable monomer correspond ding to the general formula (IV) and a radical-polymerizable macromonomer corresponding to the general formula (V) using a known radical polymerization initiator. Here, the monomer corresponding to the general formula (IV) is a monomer represented by the following general formula (IVM), and the macromonomer corresponding to the general formula (V) is a macromonomer represented by the following general formula (VM).

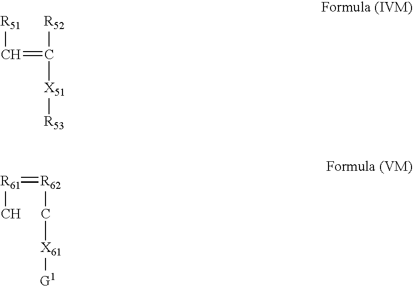

Additionally, individual signs in the general formulae (IVM) and (VM) are the same as those in the general formulae (IV) and (V).

As the monomers represented by the general formula (IVM), there are illustrated, for example, (meth)acrylates such as methyl(meth)acrylate, ethyl(meth)acrylate, propyl(meth)acrylate, butyl(meth)acrylate, hexyl(meth)acrylate, octyl(meth)acrylate, 2-ethylhexyl(meth)acrylate, cyclohexyl(meth)acrylate, dodecyl(meth)acrylate, stearyl(meth)acrylate, phenyl(meth)acrylate, benzyl(meth)acrylate and 2-hydroxyethyl(meth)acrylate; (meth)acrylamides such as N-methyl(meth)acrylamide, N-propyl(meth)acrylamide, N-phenyl(meth)acrylamide, N,N-dimethyl(meth)acrylamide; styrenes such as styrene, methylstyrene, chlorostyrene and methoxystyrene; hydrocarbons such as 1-butene; vinyl acetates; vinyl ethers; and vinylpyridines.

The macromonomer represented by the general formula (VM) is a monomer having a radical-polymerizable functional group at one end thereof which is obtained by polymerizing a radical-polymerizable monomer of the following general formula (VIM) corresponding to the general formula (VI) in the presence of, as needed, a chain transfer agent and introducing a radical-polymerizable functional group into one end of the thus-obtained polymer.

Additionally, the weight-average molecular weight of the macromonomer represented by the general formula (VM) is in the range of preferably from 500 to 500,000, and the polydispersity (weight-average molecular weight/number-average molecular weight) of the macromonomer is in the range of preferably from 1.0 to 7.0. Further, the macromonomer represented by the general formula (VM) may be a polydimethylsiloxane having a radical-polymerizable functional group on the end thereof.

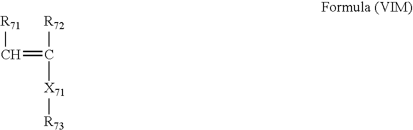

Additionally, individual signs in the general formula (VIM) are the same as those in the general formula (VI).

As the monomers represented by the general formula (VIM), there are illustrated, for example, (meth)acrylates such as methyl(meth)acrylate, ethyl(meth)acrylate, propyl(meth)acrylate, butyl(meth)acrylate, hexyl(meth)acrylate, octyl(meth)acrylate, 2-ethylhexyl(meth)acrylate, cyclohexyl(meth)acrylate, dodecyl(meth)acrylate, stearyl(meth)acrylate, phenyl(meth)acrylate, benzyl(meth)acrylate and 2-hydroxyethyl(meth)acrylate; (meth)acrylamides such as N-methyl(meth)acrylamide, N-propyl(meth)acrylamide, N-phenyl(meth)acrylamide, N,N-dimethyl(meth)acrylamide; styrenes such as styrene, methylstyrene, chlorostyrene and methoxystyrene; hydrocarbons such as 1-butene; vinyl acetates; vinyl ethers; and vinylpyridines.

The graft polymer to be used in the invention may have only the constituting units represented by the general formulae (IV) and (V), and may have other constituting unit. As specific examples of the graft polymer to be preferably used in the invention, polymers [BZ-1] to [BZ-8] represented by the following structural formulae are illustrated. 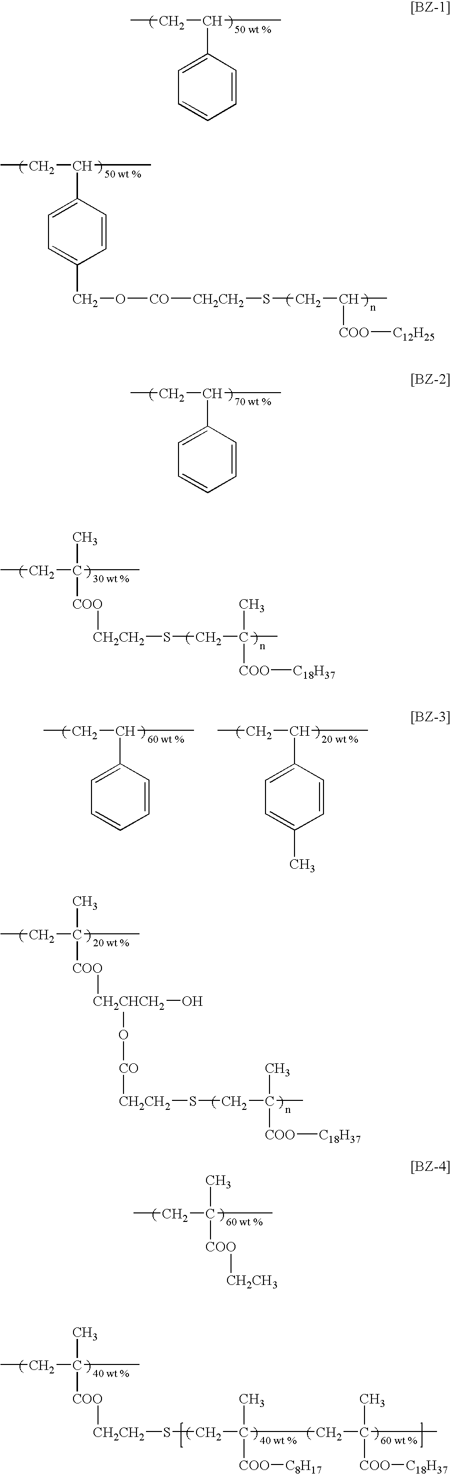 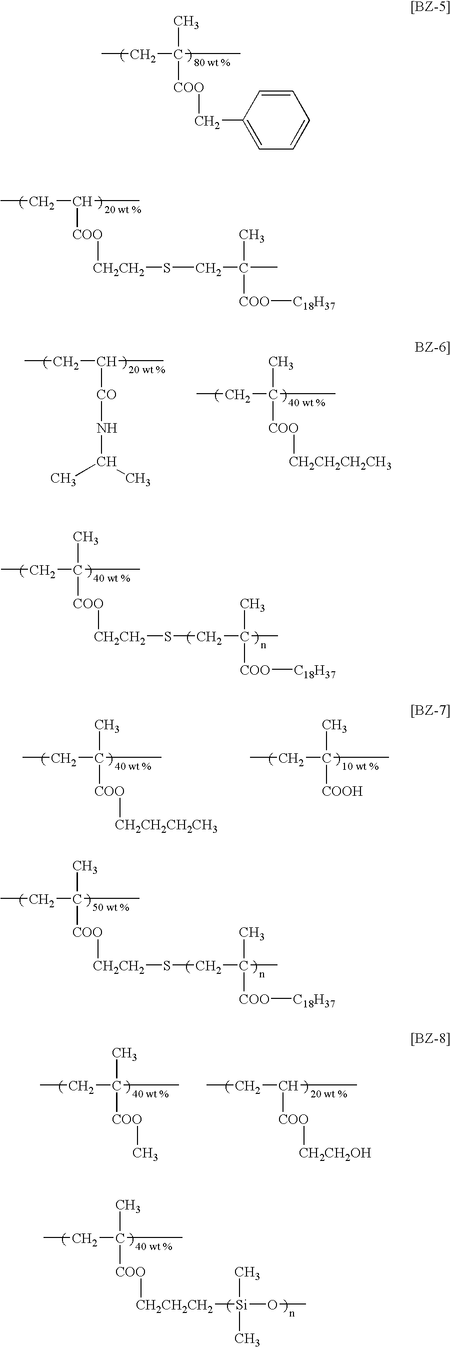
(n in the formulae represents that the moiety is a polymer, and is 5 or more.)

The term “main chain moiety is not soluble in the dispersing medium” as used herein means that a polymer not containing the constituting unit represented by the above general formula (V) has a solubility of 3 g or less for 100 g of the dispersing medium, and the term “side chain moiety is soluble in the dispersing medium” as used herein means that a polymer of G in the general formula (V) or the macromonomer of the general formula (VM) has a solubility of 5 g or more for 100 g of the dispersing medium.

In the invention, in view of long-term storage stability of particles and ejection stability, the dispersing medium is preferably a graft polymer having a weight-average molecular weight in the range of from 1,000 to 1000,000 and a polydispersity (weight-average molecular weight/number-average molecular weight) in the range of from 1.0 to 7.0.

Also, the weight-average molecular weight of the graft polymer is preferably 1.5 times as much as the weight-average molecular weight of the graft chain (preferably, the general formula 7 described above) or more than that.

Further, the weight ratio of the main chain-constituting unit to the graft chain-constituting unit is in the range of preferably from 30:70 to 95:5. These polymers may be used independently as a dispersing agent, or may be used in combination of two or more thereof to use.

As has been described hereinbefore, use of the dispersion-stabilizing resin (PF) is preferred which comprises a graft copolymer of a soluble component and an insoluble component containing at least the constituting unit represented by the foregoing general formula (IV) and the constituting unit represented by the foregoing general formula (V). In this case, the main chain moiety of the insoluble component in the dispersion-stabilizing resin (PF) sufficiently adsorbs onto insoluble resin particles. Further, use of the dispersion-stabilizing resin (PG) having a polymerizable double bond group is preferred. In this case, the resin (PG) forms chemical bond with the insoluble resin particles. Thus, affinity of the soluble component of the dispersion-stabilizing resin (P) sufficiently adsorbing on, or chemically bound to, the dispersed resin particles is improved, which provides so-called steric repulsion effect, thus dispersibility being supposedly more improved.

The weight-average molecular weight (Mw) of the dispersing agent (P) of the invention is preferably from 2×10⁴ to 1×10⁶, more preferably from 3×10⁴ to 2×10⁵.

(Radical-Polymerizable Monomer)

At least two kinds of radical-polymerizable monomers to be used in the invention include (A) a radical-polymerizable monomer (a first radical-polymerizable monomer) having a nucleophilic group and (B) a radical-polymerizable monomer (a second radical-polymerizable monomer) having a group (electrophilic group) capable of reacting with the nucleophilic group to form a covalent bond (hereinafter in some cases referred to radical-polymerizable monomers (A) and (B), respectively).

Specific examples of the radical-polymerizable monomers (A) and (B) are described in, for example, technical books on organic chemistry, such as Daigakuin Kogi Yuki Kagaku I (Bunshi Kozo To Hanno•Yuki Kinzoku Kagaku) compiled by Ryoji Noyori et al. (Tokyo Kagaku Dojin), Yuki Kagaku (Organic Chemistry) written by Morrison Boyd (Tokyo Kagaku Dojin), and Yuki Kagaku (Organic Chemistry) written by McMurry (Tokyo Kagaku Dojin).

Additionally, combination of the radical-polymerizable monomers (A) and (B) is not particularly limited but, as preferred combinations, there are illustrated a combination of (A) a radical-polymerizable monomer having a carboxyl group, a primary amino group, a secondary amino group, a phenoxy group, an alkoxy group, a hydroxyl group, a thiol group, a thioalkoxy group, a thiophenoxy group, a —COCHCO— group, a —COCHSO₂— group, a —CONHSO₂— group or a —SO₂NHSO₂— group and (B) a radical-polymerizable monomer having an epoxy group, an isocyanato group, a thioisocyanato group, an oxetane group, a fluoroalkyl group, a chloroalkyl group, a bromoalkyl group, an iodoalkyl group, a sulfonic acid group, a trifluoromethanesulfonic acid alkyl group, a perfluoroalkanesulfonic acid alkyl group such as pentafluoroethanesulfonic acid alkyl group, tosylic acid alkyl group or a perfluoroalkanecarboxylic acid alkyl group.

A more preferred combination is (A) a radical-polymerizable monomer having a carboxyl group, an alkoxy group, a secondary amino group or a thiol group and (B) a radical-polymerizable monomer having an epoxy group, an isocyanato group, a thioisocyanato group, a chloroalkyl group or a bromoalkyl group.

Examples of reactions for forming a covalent bond by reacting the radical-polymerizable monomers (A) and (B) are shown below. R¹ to R³ each represents an arbitrary substituent.
Nucleophilic Group Electrophilic Group

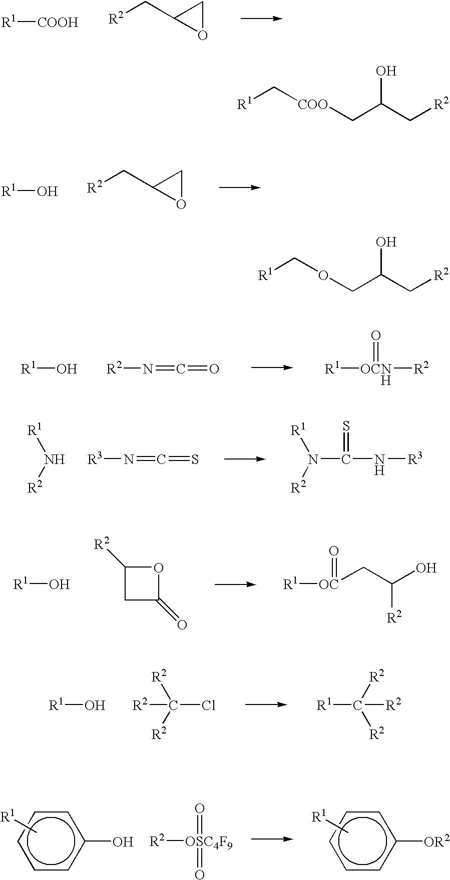

Specific examples of the radical-polymerizable monomer (A) are shown below.

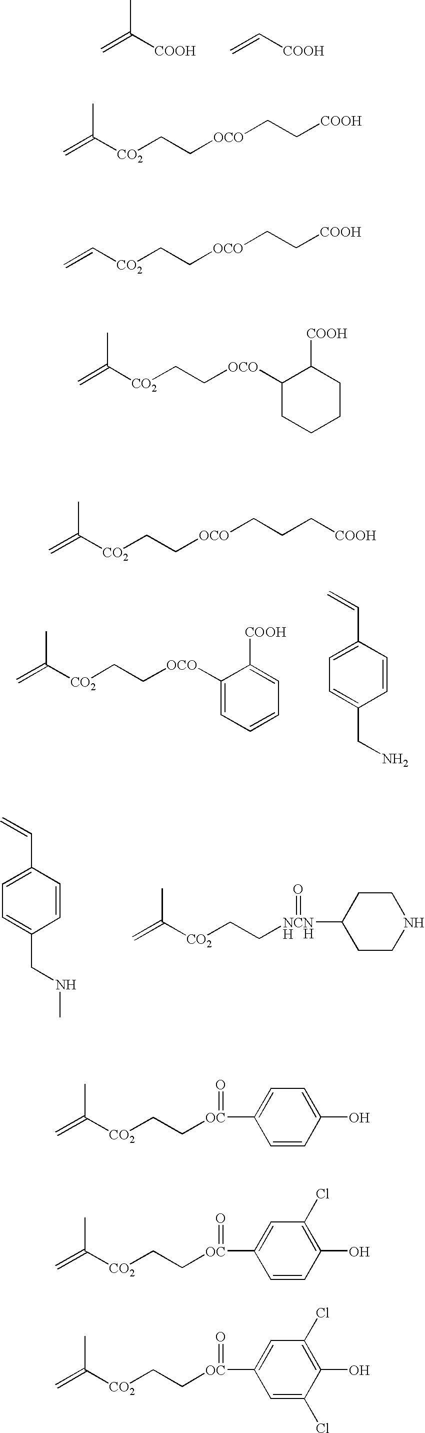

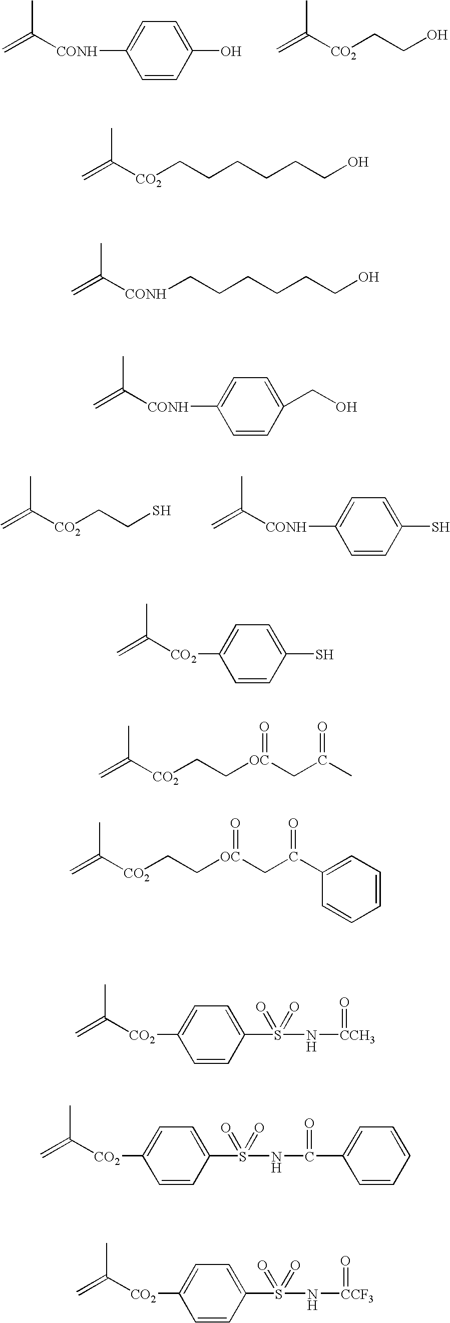

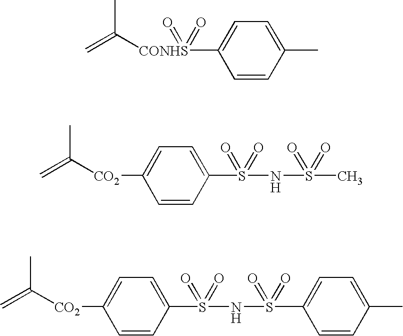

Specific examples of the radical-polymerizable monomer (B) are shown below.

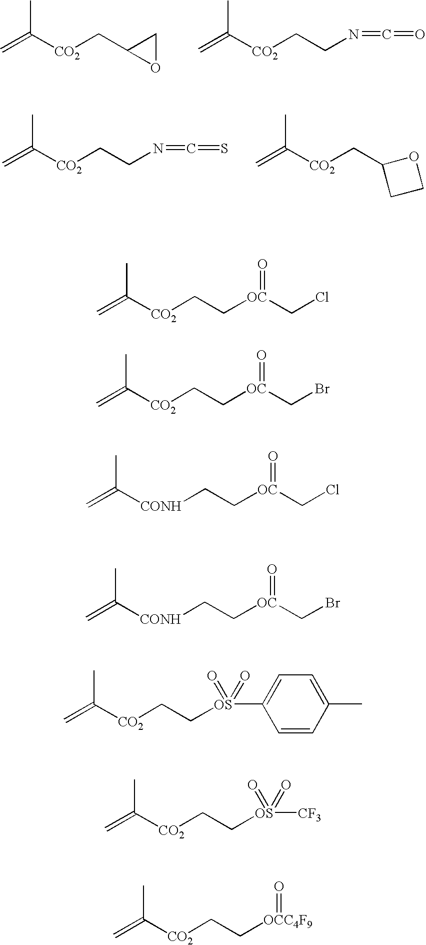

In order to control particle-forming properties, particle dispersibility and particle chargeability, other known radical-polymerizable monomers than the radical-polymerizable monomers (A) and (B) may be used as the radical-polymerizable monomers to be used in the invention. The other radical-polymerizable monomers are preferably monofunctional monomers which are soluble in a non-aqueous solvent but, after polymerization, become insoluble. Specifically, there are illustrated, for example, monomers represented by the following general formula (X).

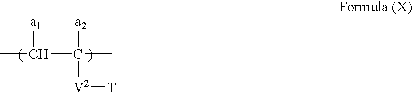

In the general formula (X), V² represents a single bond, —COO—, —OCO—, —CH₂OCO—, —CH₂COO—, —O—, —CONHCOO—, —CONHOCO—, —SO₂—, —CON(Q¹)-, —SO₂N(Q¹)- or a phenylene group (hereinafter the phenylene group being in some cases represented by “-Ph-”; additionally, the phenylene group including a 1,2-phenylene group, a 1,3-phenylene group and a 1,4-phenylene group). Here, Q¹ represents a hydrogen atom or an optionally substituted aliphatic group containing from 1 to 8 carbon atoms (e.g., a methyl group, an ethyl group, a propyl group, a butyl group, a 2-chloroethyl group, a 2-bromoethyl group, a 2-cyanoethyl group, a 2-hydroxyethyl group, a benzyl group, a chlorobenzyl group, a methylbenzyl group, a methoxybenzyl group, a phenethyl group, a 3-phenylpropyl group, a dimethylbenzyl group, a fluorobenzyl group, a 2-methoxyethyl group or a 3-methoxypropyl group).

T represents a hydrogen atom or an optionally substituted aliphatic group containing from 1 to 6 carbon atoms (e.g., a methyl group, an ethyl group, a propyl group, a butyl group, a 2-chloroethyl group, a 2,2-dichloroethyl group, a 2-bromoethyl group, a 2-hydroxyethyl group, a 2-hydroxypropyl group, a 2,3-dihydroxypropyl group, a 2-hydroxy-3-chloropropyl group, a 2-cyanoethyl group, a 3-cyanopropyl group, a 2-nitroethyl group, a 2-methoxyethyl group, a 2-methanesulfonylethyl group, a 2-ethoxyethyl group, a 3-bromopropyl group, a 4-hydroxybutyl group, a 2-furfurylethyl group, a 2-thienylethyl group, a 2-carboxyethyl group, a 3-carboxypropyl group, a 4-carboxybutyl group, a 2-carboxamidoethyl group, a 2-N-methylcarboxamidoethyl group, a cyclopentyl group, a chlorocyclohexyl group or a dichlorohexyl group).

a¹ and a², which may be the same or different, each preferably represents a hydrogen atom, a halogen atom (e.g., a chlorine atom or a bromine atom), a cyano group, an alkyl group containing from 1 to 3 carbon atoms (e.g., a methyl group, an ethyl group or a propyl group), —COO-Q² or —CH₂—COO-Q² [wherein Q² represents a hydrogen atom or an optionally substituted hydrocarbon group containing 10 or less carbon atoms (e.g., an alkyl group, an alkenyl group, an aralkyl group or an aryl group).

As specific examples of the radical-polymerizable monomers, there are illustrated, for example, vinyl esters or allyl esters of an aliphatic carboxylic acid containing from 1 to 6 carbon atoms (e.g., acetic acid, propionic acid, butyric acid or monochloroacetic acid); alkyl esters or amides of an unsaturated carboxylic acid such as acrylic acid, methacrylic acid, crotonic acid, itaconic acid or maleic acid with the alkyl group containing from 1 to 4 carbon atoms and being optionally substituted (examples of the alkyl group being a methyl group, an ethyl group, a propyl group, a butyl group, a 2-chloroethyl group, a 2-bromoethyl group, a 2-hydroxyethyl group, a 2-cyanoethyl group, a 2-nitroethyl group, a 2-methoxyethyl group, a 2-methanesulfonylethyl group, a 2-benzenesulfonylethyl group, a 2-carboxyethyl group, a 4-carboxybutyl group, a 3-chloropropyl group, a 2-hydroxy-3-chloropropyl group, a 2-furfurylethyl group, a 2-thienylethyl group and a 2-carboxamidoethyl group); styrene derivatives (e.g., styrene, vinyltoluene, α-methylstyrene, vinylnaphthalene, chlorostyrene, dichlorostyrene, bromostyrene, vinylbenzenecarboxylic acid, chloromethylstyrene, hydroxymethylstyrene, methoxymethylstyrene, vinylbenzenecarboxamide and vinylbenzenesulfamide); unsaturated carboxylic acids such as acrylic acid, methacrylic acid, crotonic acid, maleic acid and itaconic acid; cyclic anhydrides of maleic acid and itaconic acid; acrylonitrile; methacrylonitrile; and polymerizable double bond-containing hetero ring compounds (specifically compounds described in, for example, Kobunshi Data Handbook—Kisohen— (High Polymer Data Handbook—Basic Course—) compiled by Kobunshi Gakkai, pp. 175-184, Baifukan (published in year 1986) and are exemplified by N-vinylpyridine, N-vinylimidazole, N-vinylpyrrolidone, vinylthiophene, vinyltetrahydrofuran, vinyloxazoline, vinylthiazole and N-vinylmorpholine).

With the fine particles of the invention, it is preferred to use a radical-polymerizable monomer having a cationic group for the purpose of imparting positive charge to the particles in a non-aqueous solvent. The radical-polymerizable monomers having a cationic group are monomers having at least one amino group represented by the general formula (Y) within the molecule and polymerizable monomers having a nitrogen-containing hetero ring.

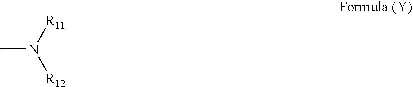

In the general formula (Y), R₁₁ and R₁₂, which may be the same or different, each represents a hydrogen atom or a hydrocarbon group containing from 1 to 22 carbon atoms. R₁₁ and R₁₂ may be connected to each other to form a ring.

As the nitrogen-containing hetero ring, there can be illustrated pyridine, imidazole, indole, carbazole and quinoline. As a preferred structure, there can be illustrated those radical-polymerizable monomers of the general formula (X) wherein the amino group represented by the general formula (Y) is connected to the atoms represented by T. Specifically, there can be illustrated dimethylaminoethyl methacrylate, diethylaminoethyl methacrylate, dimethylaminopropyl methacrylate, dibutylaminoethyl methacrylate, 4-vinylpyridine, 3-vinylpyridine, vinylimidazole and N-vinylcarbazole.

In the case of imparting positive charge to the surface of the resin particles, the cationic monomer can be mixed with the aforesaid radical-polymerizable monomer in any proportion to use. The proportion of the cationic monomer is preferably from 1 to 50% by weight, more preferably from 5 to 30% by weight, based on the total weight of the radical-polymerizable monomer and the cation-polymerizable monomer.

Such radical-polymerizable monomers may be used in combination of two or more thereof.

Of the radical-polymerizable monomers to be used in polymerization, the proportion of the total amount of the radical-polymerizable monomers (A) and (B) is from 0.1 to 100 mol %, preferably from 1 to 95 mol %, more preferably from 10 to 90 mol %, per mol of the whole monomers.

The molar ratio of the radical-polymerizable monomer (A)/the radical-polymerizable monomer (B) is generally from 9/1 to 1/9, preferably from 8/2 to 2/8.

(Polymerization Initiator)

As the polymerization initiator to be used in polymerization, those peroxide series or azo series initiators which are commonly used in radical polymerization can be utilized. For example, there are illustrated peroxide series initiators such as benzoyl peroxide, lauroyl peroxide, octanoyl peroxide, o-chlorobenzoyl peroxide, o-methoxybenzoyl peroxide, methyl ethyl ketone peroxide, diisopropylperoxydicarbonate, cumene hydroperoxide, cyclohexanone peroxide, t-butyl hydroperoxide and diisopropylbenzene hydroperoxide; 2,2′-azobisisobutyronitrile; 2,2′-azobis(2,4-dimethylvaleronitrile); 2,2′-azobis(2,3-dimethylbutyronitrile); 2,2′-azobis(2-methylbutyronitrile); 2,2′-azobis(2,3,3-trimethylbutyronitrile); 2,2′-azobis(2-isopropylbutyronitrile); 1,1′-azobis(cyclohexane-1-carbonitrile); 2,2′-azobis(4-methoxy-2,4-dimethylvaleronitrile); 2-(carbamoylazo)isobutyronitrile; 4,4′-azobis(4-cyanovaleric acid); and dimethyl-2,2′-azobisisobutyrate. The polymerization initiator is used in an amount of preferably from 0.01 to 20% by weight, particularly preferably from 0.1 to 10% by weight, based on the weight ofthe radical-polymerizable monomers.

(Synthesis of Non-Truly-Spherical High-Molecular Fine Particles (CR))

The non-truly-spherical high-molecular fine particles of the invention can be obtained by radical polymerization of the radical-polymerizable monomers (A) and (B) in a non-aqueous solvent in the presence of the dispersion-stabilizing resin (P).

Specifically, there are a process of adding a polymerization initiator to a mixture of the dispersion-stabilizing resin (P), the radical-polymerizable monomers (A) and (B) and a non-aqueous solvent; a process of dissolving the dispersion-stabilizing resin (P) in a non-aqueous solvent, and dropwise adding thereto a polymerization initiator together with, as needed, a non-aqueous solvent; and the like. The fine particles can be produced by any of the processes.

In polymerization, the concentration of the monomers is in the range of preferably from 5 to 50% by weight, more preferably from 10 to 40% by weight, based on the total weight of the whole polymerizable monomers, the non-aqueous solvent and the dispersion-stabilizing resin (P) used for the polymerization.

The heating temperature can be determined according to the decomposition temperature of the polymerization initiator used, and is generally from 30 to 120 C, preferably from 50 to 100° C.

The polymerization is preferably conducted in a stream of an inert gas such as nitrogen.

The average particle size of the thus-obtained non-truly-spherical high-molecular fine particles (CR) is preferably from 0.05 to 10 μm, more preferably from 0.1 to 5 μm. The resin particles of the invention having an average particle size of from about 0.1 to about 5 μm and good mono-disperse properties can easily be obtained by using such particles.

The non-truly-spherical high-molecular fine particles (CR) may be concentrated or diluted in the non-aqueous solvent. Or, in order to purify the resin particles, the particles may be precipitated by centrifugation to separate from the supernatant solution and re-dispersing the separated particles in the non-aqueous solvent to use.

The non-truly-spherical high-molecular fine particles (CR) can also be formed by first forming resin particles (CR0) from a radical-polymerizable monomer not containing the radical-polymerizable monomers (A) and (B), and then adding thereto radical-polymerizable monomers (feed monomers) containing the radical-polymerizable monomers (A) and (B) and a polymerization initiator using the formed particles as seed particles.

In this case, regarding the proportion of the resin particles (CR0) and the total weight of the radical-polymerizable monomers (feed monomers) containing the radical-polymerizable monomers (A) and (B) used, the weight ratio of the resin particles (CR0)/total weight of the feed monomers is preferably from 5/95 to 95/5, more preferably from 10/90 to 80/20. The total weight of the resin particles (CR0) and the total radical-polymerizable monomers is preferably from 10 to 150 parts by weight, more preferably from 10 to 100 parts by weight, per 100 parts by weight of the non-aqueous solvent.

The amount of the dispersion-stabilizing resin (P) to be used is preferably from 3 to 40 parts by weight, more preferably from 5 to 30 parts by weight, per 100 parts by weight of the total monomers to be used. The amount of the polymerization initiator is suitably from 0.1 to 10% by weight. The polymerization temperature is preferably from about 40 to about 180° C., more preferably from 50 to 120° C. The reaction time is preferably from about 5 to about 20 hours.

(Inkjet Ink Composition, Oily Ink Composition for Inkjet Type Lithographic Printing Plate and Electrophoretic Particles-Containing Composition)

The non-truly-spherical high-molecular fine particles are useful as chargeable particles in an inkjet ink composition, an oily ink composition for inkjet type lithographic printing plate and an electrophoretic particles-containing composition (hereinafter inclusively referred to merely as “composition”).

(Dyeing)

The high-molecular fine particles of the invention are preferably colored, as needed, for using in an inkjet ink and an electrophoretic display device. As the coloring agent, any known coloring agent of pigment or dye for an oily ink composition or for a liquid developer for electrostatic photography can be used.

As the pigment, those pigments which are commonly used in the field of printing can be used regardless of whether they are inorganic pigments or organic pigments. Specifically, conventionally known pigments such as carbon black, cadmium red, molybdenum red, chromium yellow, cadmium yellow, titanium yellow, chromium oxide, viridian, titanium cobalt green, ultramarine blue, Prussian blue, cobalt blue, azo pigments, phthalocyanine pigments, quinacridone pigments, isoindolinone pigments, dioxazine pigments, threne pigments, perylene pigments, perinone pigments, thioindigo pigments, quinophthalone pigments and metal complex pigments can be used with no particular limitation.

As the dyes, oil-soluble dyes such as azo dyes, metal chelate salt dyes, naphthol dyes, anthraquinone dyes, indigo dyes, carbonium dyes, quinoneimine dyes, xanthene dyes, cyanine dyes, quinoline dyes, nitro dyes, nitroso dyes, benzoquinone dyes, naphthoquinone dyes, phthalocyanine dyes and metal phthalocyanine dyes are preferred.

These pigments and dyes may be used independently or in proper combination thereof, and are desirably incorporated in a content of from 0.01 to 5% by weight based on the entire composition.

These coloring agents may be dispersed in a non-aqueous solvent as dispersed color agent particles separate from the dispersed non-truly-spherical high-molecular fine particles or may be incorporated in the high-molecular fine particles. As one method for incorporating the coloring agent, there is a method of dyeing the high-molecular fine particles with a preferred dye as described in, for example, JP-A-57-48738. Or, as another method, there is a method of chemically binding the high-molecular fine particles and the dye to each other as disclosed in, for example, JP-A-53-54029. Further, there is a method of using a monomer previously containing a dye upon producing the particles by the process of forming particles by polymerization to form a dye-containing copolymer as described in, for example, JP-B-44-22955.

In order to dye the non-truly-spherical high-molecular fine particles obtained by polymerization of the radical-polymerizable monomers in the non-aqueous solvent in the presence of the dispersion-stabilizing resin (P), there are illustrated a method of mixing a dye powder with a dispersion of the non-truly-spherical high-molecular fine particles and heating the mixture under stirring. In view of uniformity of dyeing, however, a dye solution using an organic solvent can be used. As the organic solvent to be used in this case, those solvents can be used which can dissolve the dye and which, when added to the dispersion of the non-truly-spherical high-molecular fine particles in the non-aqueous solvent, do not dissolve or agglomerate the high-molecular fine particles. Organic solvents slightly swelling the high-molecular fine particles may also be used. As specific examples, there can be illustrated methanol, ethanol, acetone, methyl ethyl ketone, ethyl acetate, dichloromethane and chloroform.

The concentration of the dye solution is in the range of preferably from 0.01 to 10% by weight, more preferably from 0.1 to 5% by weight. The dye solution is added in an amount ranging preferably from 1 to 20 parts by weight per 100 parts by weight of the dispersion of the non-truly-spherical high-molecular fine particles in the non-aqueous solvent. The heating temperature is preferably from 25° C. to 100° C., more preferably from 30° C. to 80° C. The solvent used for dissolving the dye may be distilled off after heating.

In the case of using the non-aqueous solvent and the polar solvent such as an alcohol, a ketone, an ether or an ester or in the case where non-reacted radical-polymerizable monomers remain after polymerization, it is possible to remove the polar solvent or the non-reacted monomers by heating to distill off or by distilling under reduced pressure, or to separate the non-truly-spherical high-molecular fine particles from the solvent by centrifugation.

The thus-obtained non-truly-spherical high-molecular fine particles exist as fine particles with uniform particle size distribution. The average particle size is preferably from 0.1 to 3.0 μm, more preferably from 0.15 to 2.0 μm. This particle size can be determined by means of a centrifugal sedimentation type particle size distribution analyzer (e.g., CAPA-700; manufactured by Horiba, Ltd.) or a laser diffraction/scattering particle size distribution analyzer (e.g., LA-920; manufactured by Horiba, Ltd.).

In the inkjet ink composition of the invention, the non-truly-spherical high-molecular fine particles are used in an amount of preferably from 0.001 to 10 parts by weight per 100 parts by weight of the non-aqueous solvent which is a supporting liquid.

(Charge-Adjusting Agent)

Next, as the charge-adjusting agent which can be used in the invention, conventionally known ones can be used. For example, there can be used metal salts of fatty acids such as naphthenic acid, octenoic acid, oleic acid and stearic acid; metal salts of sulfosuccinates; oil-soluble metal sulfonates disclosed in JP-B-45-556, JP-A-52-37435 and JP-A-52-37049; metal phosphates disclosed in JP-B-45-9594; metal salts of abietic acid or hydrogenated abietic acid disclosed in JP-B-48-25666; Ca salts of alkylbenzenesulfonates disclosed in JP-A-55-2620; metal salts of aromatic carboxylic acid or sulfonic acid disclosed in JP-A-52-107837, JP-A-52-38937, JP-A-57-90643 and JP-A-57-139753; nonionic surfactants such as polyoxyethylated alkylamines; fats and oils such as lecithin and linseed oil; polyvinylpyrrolidone; organic acid esters of polyhydric alcohols; phosphate series surfactants disclosed in JP-B-57-210345; and sulfonic acid resins disclosed in JP-B-56-24944. Amino acid derivatives described in JP-A-60-21056 and JP-A-61-50951 can also be used. Further, there are illustrated copolymers containing a maleic acid half amide component described in JP-A-60-173558 and JP-A-60-179750. Further, there can be illustrated quaternary amine polymers disclosed in JP-A-54-31739 and JP-B-56-24944.

Of these, metal salts of naphthenic acid, metal salts of dioctylsulfosuccinic acid, copolymers containing a maleic acid half amide component, lecithin and amino acid derivatives can be illustrated as preferred ones. It is possible to use two or more compounds in combination thereof as the charge-adjusting agents. The concentration of the charge-adjusting agent as described above is in the range of preferably from 0.0001 to 2.0% by weight based on the total weight of the composition. That is, the concentration of the charge-adjusting agent is preferably 0.0001% by weight or more in view of high specific conductivity of the particles, and is preferably 2.0% by weight or less in view of maintaining necessary printing density.

(Other Additives)

The fundamental constituting materials in the invention are the components as described hereinbefore and, as needed, various additives may be added to the composition of the invention. Such additives are selected with no limitation depending upon the inkjet system or kind of materials or structures of an inkjet-ejecting head, an ink-feeding part and an ink-circulating part, and are incorporated in the ink composition. For example, those additives are used which are described in, for example, Inkjet Printer Gijutsu To Zairyo, chapter 17, supervised by Takeshi Amari and published by K.K. CMC in year 1998.

Specifically, there are illustrated fatty acids (e.g., monocarboxylic acids containing from 6 to 32 carbon atoms and polybasic acids; such as 2-ethylhexynoic acid, dodecenylsuccinic acid, butylsuccinic acid, 2-ethylcaproic acid, lauric acid, palmitic acid, elaidic acid, linoleic acid, ricinoleic acid, oleic acid, stearic acid, enanthic acid, naphthenic acid, ethylenediaminetetraacetic acid, abietic acid, dehydroabietic acid and hydrogenated rosin), metal salts of resin acid, alkylphthalic acid and alkylsalicylic acid (examples of metals of metal ions being Na, K, Li, B, Al, Ti, Ca, Pb, Mn, Co, Zn, Mg, Ce, Ag, Zr, Cu, Fe and Ba), surface active compounds (examples of organic phosphoric acids or the salts thereof being mono-, di- or tri-alkylphosphoric acids wherein the alkyl group contains from 3 to 18 carbon atoms; examples of organic sulfonic acids or the salts thereof being long-chain aliphatic sulfonic acids, long-chain alkylbenzenesulfonic acids, dialkylsulfosuccinic acids or the metal salts thereof; and examples of amphoteric surface active compounds being such phospholipids as lecithin and cephalin), surfactants containing an alkyl group containing fluorine atom and/or dialkylsiloxane bond group, aliphatic alcohols (e.g., higher alcohols comprising a branched alkyl group containing from 9 to 20 carbon atoms, benzyl alcohol, phenethyl alcohol and cyclohexyl alcohol), polyhydric alcohols {e.g., alkylene glycols containing from 2 to 18 carbon atoms (ethylene glycol, 1,2-propylene glycol, 1,3-propylene glycol, 1,4-butanediol, neopentyl glycol, 1,6-hexanediol and dodecanediol); alkylene ether glycols containing from 4 to 1000 carbon atoms (e.g., diethylene glycol; triethylene glycol, dipropylene glycol; polyethylene glycol; polypropylene glycol and polytetramethylene ether glycol), alicyclic diols containing from 5 to 18 carbon atoms (e.g., 1,4-cyclohexanedimethanol and hydrogenated bisphenol A), adducts of alkylene oxides containing from 2 to 18 carbon atoms (e.g., ethylene oxide, propylene oxide, butylenes oxide and α-olefin oxide) to bisphenols containing from 12 to 23 carbon atoms (e.g., bisphenol A, bisphenol F and bisphenol S), polyols such as glycerin, trimethylolethane, trimethylolpropane, pentaerythritol and sorbitol, phenols having 3 to 8 or more hydroxyl groups (e.g., tris-phenol PA, phenol novolak and cresol novolak) and adducts of alkylene oxide containing from 2 to 18 carbon atoms to the polyphenols having 3 or more hydroxyl groups (mol number of added alkylene oxide being from 2 to 20)}, ether derivatives of the above-mentioned polyhydric alcohols (e.g., polyglycol alkyl ethers and alkylaryl polyglycol ethers), fatty acid ester derivatives of the polyhydric alcohols, ether oleate derivatives of the polyhydric alcohols (e.g., ethylene glycol monoethyl acetate, diethylene glycol monobutyl acetate, propylene glycol monobutyl propiolate and sorbitan monomethyldioxalate), alkylnaphthalenesulfonates and alkylarylsulfonates which, however, are not limitative at all.

The amounts of individual additives to be used are preferably adjusted so that the surface tension of the composition falls within the range of from 15 to 60 mN/m (at 25° C.) and the viscosity thereof falls within the range of from 1.0 to 40 cP.

(Inkjet Ink Composition)

The composition containing the non-truly-spherical high-molecular fine particles of the invention can be subjected to inkjet recording as an inkjet ink composition in an inkjet recording device.

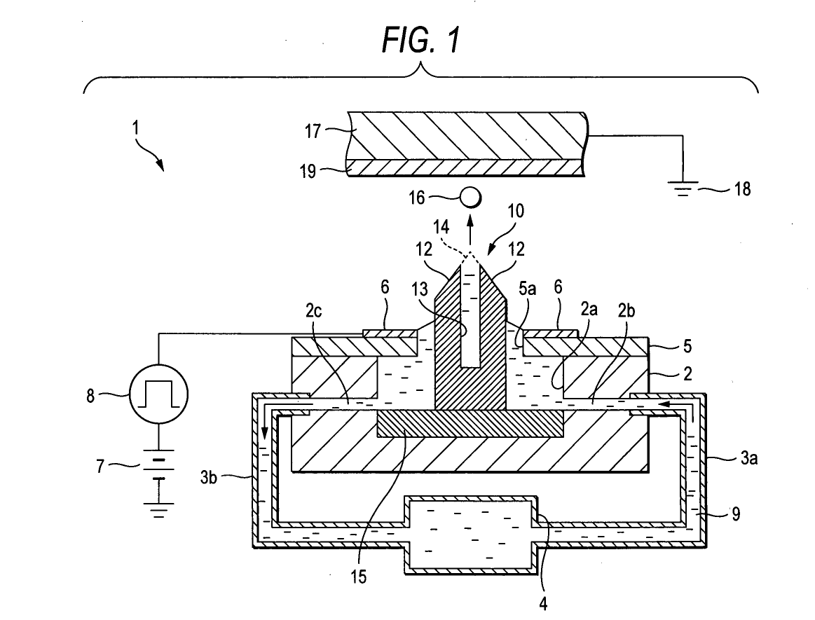

FIG. 1 is a drawing which shows the constitution of an inkjet recording device adequate for the ink composition of the invention, wherein a cross section of a part including a unit electrode corresponding to each recording dot and peripheral portions thereof is shown. In FIG. 1, a line-scanning type inkjet head 1 is equipped with a head block 2 having an ink reservoir 2a, an insulating substrate 5 provided on the ink-ejecting side of the head block 2, which substrate has a substrate-penetrating hole 5a corresponding to the ink reservoir 2a, a controlling electrode 6 provided so as to surround the substrate-penetrating hole 5a for applying a voltage to chargeable ink 9, a bias voltage source 7 for constantly feeding a definite bias voltage to this controlling electrode 6, a signal voltage source 8 for feeding to the controlling electrode 6 a signal corresponding to an image to be recorded, and a projecting ink guide 10 provided within the ink reservoir 2a and the substrate-penetrating hole 5a.

On both side of the head block 2 are formed, respectively, an ink-feeding flow passage 2b and an ink-recovering flow passage 2c for circulating an ink. An ink-feeding pipe 3a and ink-recovering pipe 3b are connected to the ink-feeding flow passage and the ink-recovering flow passage 2c, respectively. The ink-feeding pipe 3a and the ink-recovering pipe 3b are connected to an ink-circulating mechanism 4.

The projecting ink guide 10 is held, through a given method, by the head substrate 15 positioned at the bottom of the head block 2. Further, this projecting ink guide 10 has a cross-sectional shape of a piece of shogi (Japanese chess) having tilt portions 12 tilting on both sides with the same thickness, and is notched along the center line with a predetermined width from the top where the tilt portions 12 cross, thus forming an ink guide groove 13. The ink having crept along this ink guide groove 13 based on capillarity is ejected toward an opposed electrode 17 as an ink droplet from an ink droplet-ejecting position 14. The opposed electrode 17 is provided with a predetermined voltage level by an earth source 18, and this opposed electrode 17 functions as a platen and holds a recording medium 19.

This inkjet head 1 is equipped with a plurality of unit electrodes corresponding to individual recording dots and, in FIG. 1, the ink 9 is an ink wherein ink particles having positive chargeability are dispersed and suspended in a colloidal state in an insulating solvent having a resistivity of 10⁸ Ωcm or more. This ink 9 is fed to the ink reservoir 2a positioned between the head substrate 15 and the insulating substrate 5 from the ink-feeding flow passage 2b formed within the head block 2 through an ink-circulating mechanism 4 including a pump (not shown) and through an ink-feeding pipe 3a, and is recovered by the ink-circulating mechanism 4 through the ink-recovering passage 2c and the ink-recovering pipe 3b similarly formed within the head block 2.

The insulating substrate 5 is an insulating substrate having the substrate-penetrating hole 5a, and a controlling electrode substrate is constituted by the controlling electrode 6 formed around the substrate-penetrating aperture 5a on the recording medium side of the insulating substrate 5. On the other hand, the projecting ink guide 10 is disposed on the head substrate 15 so that the projecting ink guide 10 is positioned at about the center of the substrate-penetrating aperture 5a.

(Oily Ink Composition for Inkjet Type Lithographic Printing Plate)

A composition containing the non-truly-spherical high-molecular fine particles of the invention can be used as an oily ink composition for inkjet type lithographic printing plate for preparing a printing plate.

The water-resistant support having a hydrophilic surface permitting lithographic printing may be a support which provides a hydrophilic surface suited for lithographic printing, and conventional supports to be subjected to offset printing plates can be used as such. Specifically, substrates having a hydrophilic surface such as plastic sheets, paper equipped with printing durability, aluminum plates, zinc plates, bi-metal plates such as copper-aluminum plates, copper-stainless steel plates and chromium-copper plates, and tri-metal plates such as chromium-copper-aluminum plates, chromium-lead-iron plates and chromium-copper-stainless steel plates are used. The thickness is preferably from 0.1 to 3 mm, particularly from 0.1 to 1 mm.

With a support having an aluminum surface, the surface is preferably subjected to surface treatment such as graining treatment, treatment of dipping in an aqueous solution of sodium silicate, potassium fluorozirconate or a phosphate or anodizing treatment. An aluminum plate subjected to graining treatment and then to treatment of dipping in an aqueous solution of sodium silicate as described in U.S. Pat. No. 2,714,066, and an aluminum plate subjected to anodizing treatment and then to treatment of dipping in an aqueous solution of an alkali metal silicate as described in JP-B-47-5125 are also preferably used.

The anodizing treatment is performed by sending an electric current using an aluminum plate in an electrolytic solution of an aqueous solution or non-aqueous solution containing inorganic acids such as phosphoric acid, chromic acid, sulfur or boric acid or organic acids such as oxalic acid and sulfamic acid or salts thereof independently or in combination of two or more thereof.

Also, electrodeposition of silicate as described in U.S. Pat. No. 3,658,662 is effective. Treatment with polyvinylsulfonic acid described in West German Non-examined Patent Publication No. 1,621,478 is adequate as well.

These hydrophilicity-imparting treatments are performed for making the surface of the support hydrophilic and, in addition, for improving adhesion properties between the surface and an ink image to be provided thereon. Also, in order to adjust adhesion properties between the support and the ink image, a surface layer may be formed on the surface of the support.

In the case where a plastic sheet or paper is used as the support, portions other than ink image areas must naturally be hydrophilic, and hence those which have a hydrophilic surface layer are used. Specifically, a known direct-draw type lithographic printing plate precursor or the same layer as the image-receiving layer of such precursor can be used.

For example, the image-receiving layer is constituted by major components of a water-soluble binder, an inorganic pigment and a water resistance imparting agent. As the binder, water-soluble resins such as PVA, modified PVA (e.g., carboxy-modified PVA), starch and the derivatives thereof, CMC, hydroxyethyl cellulose, casein, gelatin, polyvinylpyrrolidone, vinyl acetate/crotonic acid copolymer and styrene/maleic acid copolymer can be used.

As the water resistance imparting agent, glyoxal, initial condensates of aminoplast such as melamine-formaldehyde resin and urea-formaldehyde resin, modified polyamide resins such as methylol-modified polyamide resin, polyamide/polyamine/epichlorohydrin adducts, polyamide-epichlorhydrin resin and modified polyamidimide resin are illustrated. As the inorganic pigments, kaolin clay, calcium carbonate, silica, titanium oxide, zinc oxide, barium sulfate and alumina are illustrated. Of these, silica is preferred.

In addition, cross-linking catalysts such as ammonium chloride and silane coupling agent may be used together with the above-mentioned components.

Next, a method of forming an image on the lithographic printing plate precursor (hereinafter also referred to as “master”) will be described below. As a device for performing such method, there is, for example, an inkjet recording device using an oily ink as described below.

First, pattern information of an image (figures or sentences) to be formed on a master is fed from an information-feeding source such as a computer to the inkjet recording device using an oily ink through an information-transmitting means such as an information-transmitting path. The head for inkjet recording in the recording device stores therein an oily ink and, when the master passes within the recording device, the head ejects fine liquid droplets of the ink toward the master, thereby the ink being deposited on the master in the above-mentioned pattern.

Thus, formation of the image on the master is completed to obtain a lithographic printing plate.

The head provided in the inkjet recording device has a slit sandwiched by an upper unit and a lower unit, and the tip thereof forms an ink-ejecting slit. An ejecting electrode is provided within the slit, with the inside of the slit being filled with an oily ink.

In the head, a voltage is applied to the ejecting electrode according to a digital signal of the pattern information of the image. An opposed electrode is provided in the position opposed to the ejecting electrode, and a master is provided above the opposed electrode. A circuit is formed between the ejecting electrode and the opposed electrode when a voltage is applied, and the oily ink is ejected from the oily ink through the ejecting slit of the head, thus an image being formed on the master provided on the opposed electrode side.

Regarding the width of the ejecting electrode, the tip is preferably as narrow as possible in order to perform image formation with high quality, for example, letter printing.

For example, 40-μm dot letters can be printed on the master by filling the head with the oily ink, using the electing electrode of 20 μm in width of the tip, adjusting the gap between the ejecting electrode and the opposed electrode to 1.5 mm, and applying a voltage of 3 KV across the electrodes for 0.1 msec.

Additionally, in the invention, it is also preferred to add a radiation-curable compound described in JP-A-2003-192943 or JP-A-2006-8880 to the oily ink composition for the inkjet type lithographic printing plate, eject the composition onto the support and, after deposition of the composition, irradiate with radiation to cure the ink composition, thus forming hydrophobic areas to form a lithographic printing plate.

(Electrophoretic Particles-Containing Composition)

A composition containing the non-truly-spherical high-molecular fine particles of the invention, the non-aqueous solvent and the charge-adjusting agent can be applied to an electrophoretic display device as an electrophoretic particles-containing composition containing the non-truly-spherical high-molecular fine particles of the invention as electrophoretic particles.

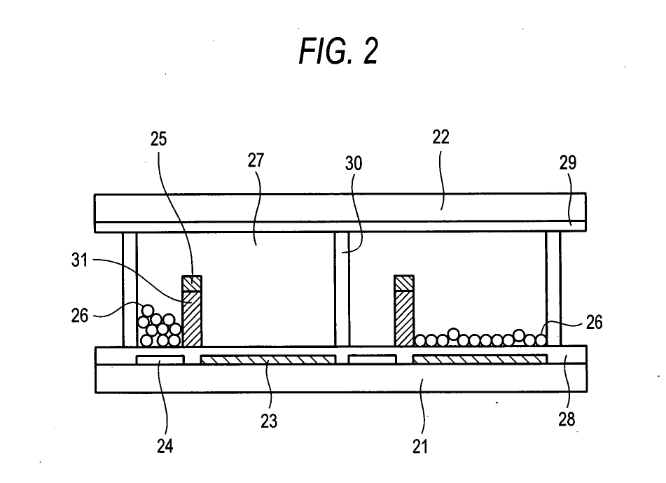

The electrophoretic display device is not particularly limited but, for example, an electrophoretic display device shown in FIG. 2 can be illustrated.

The electrophoretic display device shown in FIG. 2 has a first substrate 21, an insulating film 28 disposed on the first substrate 21 and having a first display electrode 24 and a second display electrode 23, a second substrate 22 disposed in the opposed position to the first substrate 21 and having an insulating film 29 and means for applying a desired voltage to individual electrodes and has a plurality of structural units separated from each other by partitions. In each structural unit, a controlling electrode 25 is disposed on a structural barrier 31 between the first display electrode 24 and the second display electrode 23, an electrophoretic particles-containing composition 27 is filled between the first substrate 21 and the second substrate 22, and the electrophoretic particles 26 are moved between the first display electrode 24 and the second display electrode 23, thus the display being changed.

Additionally, JP-A-2001-249366 discloses an electrophoretic display device wherein the space between the upper surface of the controlling electrode and the surface of the first substrate shown in FIG. 2 is larger than the space between the upper surface of the first display electrode and the surface of the first substrate and the space between the upper surface of the second electrode and the surface of the first substrate.

First, the first display electrode 24 and the second display electrode 23 are formed on the first substrate 21 to perform patterning. As the material for the substrate, polymer films such as polyethylene terephthalate (PET) and polyether sulfone (PES) or inorganic materials such as glass and quartz can be used. As the display electrode material, any electrically conductive material may be used that permits patterning. As the first controlling electrode material, a transparent electrode such as indium tin oxide (ITO) is used.

Next, an insulating layer is formed on the display electrode. As a material for the insulating layer, materials which difficultly form pinholes when shaped as a thin film and have a low dielectric constant are preferred. For example, amorphous fluorine-containing resin, highly transparent polyimide, PET, acrylic resin and epoxy resin can be used. The thickness of the insulating resin is preferably from about 100 nm to about 1 μm.

Next, the structural barrier 31 is formed. After successively forming the thick film for barrier, the controlling electrode film and the resist film all over the insulating layer, the uppermost resist film is patterned, followed by successively dry etching or wet etching the controlling electrode film and the thick film for forming a difference in level.

As a material for the barrier or for forming a difference in level, a polymer resin is used. As a material for the controlling electrode film or the second display electrode film, any electrically conductive material that permits patterning may be used. Such film can be formed by a metal thin film or by forming a film of ITO at a low temperature according to the magnetron sputtering method, or by using an organic electrically conductive material such as polyaniline according to the printing method. An insulating layer may be formed, as needed, on the controlling electrode 5.

The color of the controlling electrode 25 may be transparent or may be the same as either of the first display electrode or the second display electrode. Coloration of the display electrode surfaces 23 and 24 may be performed by utilizing the color of the electrode material itself or the color of the material itself of the insulating layer formed on the electrode material, or may be performed by forming a material layer having a desired color on the electrode, insulating layer or the substrate surface. Further, it is also possible to mix a coloring material into the insulating layer or the like.

Next, the insulating layer 29 and the partition 30 are formed on the second substrate. As to the material and thickness of the insulating layer, the same as has been described hereinbefore applies. Disposition of the partition 30 is not particularly limited but, in order to prevent migration of the electrophoretic particles 26 between pixels, it is preferred to dispose it so as to surround the periphery of each pixel. As a material for the partition, a polymer resin is used. The partition may be formed by any method. For example, a method of coating a light-sensitive resin layer, exposing it to light and conducting wet development, a method of adhering a separately prepared partition, a method of forming by a printing technique or a method of forming the partition on a light-transmitting first substrate surface by molding can be employed.

Next, the electrophoretic particles-containing composition of the invention is filled in the space of each pixel surrounded by the partition. The electrophoretic particles are not particularly limited as to particle size but, usually, particles with a average particle size of from 0.5 μm to 10 μm, preferably from 1 μm to 5 μm is used.

Finally, after forming an adhesive layer on the first substrate 21 at areas to be adhered to the second substrate 22, registration of the first substrate and the second substrate is performed, followed by heating to adhere them to each other. A voltage-applying means is connected to the assembly to complete a display device.

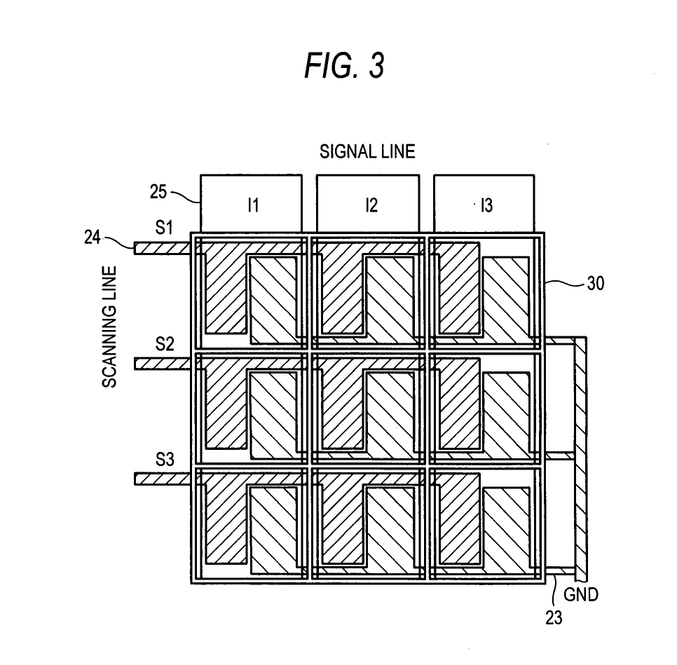

A display device as shown in, for example, FIG. 3 can be prepared by using the electrophoretic display devices shown in FIG. 2 as units. In FIG. 3, the controlling electrode 25 is used as scanning lines (S1 to S3), and the first display electrode 24 is used as the first signal line (11 to 13).

### EXAMPLES

The following Examples illustrate the invention but are not to be construed as limiting the scope of the invention.

### Example 1

(Synthesis of a Fine Particles-Containing Dispersion 1)

51 g of glycidyl methacrylate, 4 g of methacrylic acid and 8 g of a dispersion-stabilizing resin (P-1; weight-average molecular weight: 52000) of the following structure are dissolved in 135 g of Isopar G and are heated to 70° C. in a stream of nitrogen, followed by stirring for 1 hour. 0.8 g of 2,2′-azobis(2,4-dimethylvaleronitrile) is added thereto and, after heating for 2 hours under stirring, 0.8 g of 2,2′-azobis(2,4-dimethylvaleronitrile) is further added thereto, followed by heating for 2 hours under stirring. Subsequently, the temperature is raised to 100° C., and the mixture is stirred for 2 hours at a reduced pressure of 200 mmHg (about 26.6 kPa) to remove non-reacted monomers. After cooling, the reaction mixture is passed through a 200-mesh nylon cloth to obtain a white dispersion which is a latex of 98% in polymerization ratio and 26.7% in concentration of particles. The volume-average particle size is found to be 1.84 μm by measurement with an ultra-centrifugal automatic particle size distribution analyzer CAPA-700 (manufactured by Horiba, Ltd.).

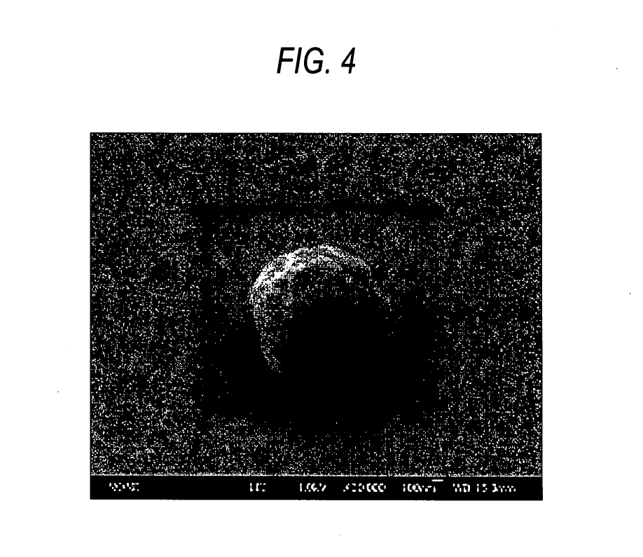

When the particles are photographed by means of an electron microscope JSM-6700F manufactured by Nihon Denshi Co., the particles are observed to be non-truly-spherical particles having uneven surface (FIG. 4: an image of a resin fine particle 1).

The particle image is photographed from the vertical direction with respect to the sample bed, and the thus-obtained image is analyzed by using an image-analyzing program, Mac-View (manufactured by Mountech Co., Ltd.), to find that the average circularity is 0.95.

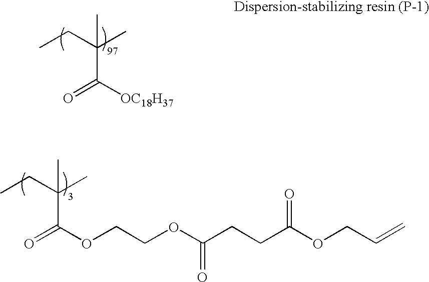

### Comparative Example 1

(Synthesis of Comparative Fine Particles-Containing Dispersion A)

51 g of methyl acrylate, 4 g of methacrylic acid and 8 g of a dispersion-stabilizing resin (P-1; weight-average molecular weight: 52000) of the above structure are dissolved in 135 g of Isopar G and are heated to 70° C. in a stream of nitrogen, followed by stirring for 1 hour. 0.8 g of 2,2′-azobis(2,4-dimethylvaleronitrile) is added thereto and, after heating for 2 hours under stirring, 0.8 g of 2,2′-azobis(2,4-dimethylvaleronitrile) is further added thereto, followed by heating for 2 hours under stirring. Subsequently, the temperature is raised to 100° C., and the mixture is stirred for 2 hours at a reduced pressure of 200 mmHg (about 26.6 kPa) to remove non-reacted monomers. After cooling, the reaction mixture is passed through a 200-mesh nylon cloth to obtain a white dispersion which is a latex of 99% in polymerization ratio and 25.8% in concentration of particles. The volume-average particle size is found to be 1.65 μm by measurement with an ultra-centrifugal automatic particle size distribution analyzer CAPA-700 (manufactured by Horiba, Ltd.).

When the particles are photographed by means of an electron microscope JSM-6700F manufactured by Nihon Denshi Co., the particles are observed to be truly-spherical particles. The particle image is photographed from the vertical direction with respect to the sample bed, and the thus-obtained image is analyzed by using an image-analyzing program, Mac-View (manufactured by Mountech Co., Ltd.), to find that the average circularity is 1.00.

### Comparative Example 2

(Synthesis of Comparative Fine Particles-Containing Dispersion B)

41 g of methyl acrylate, 4 g of methacrylic acid, 10 g of dimethylaminomethyl methacrylate and 8 g of a dispersion-stabilizing resin (P-1; weight-average molecular weight: 52000) of the above structure are dissolved in 135 g of Isopar G and are heated to 70° C. in a stream of nitrogen, followed by stirring for 1 hour. 0.8 g of 2,2′-azobis(2,4-dimethylvaleronitrile) is added thereto and, after heating for 2 hours under stirring, 0.8 g of 2,2′-azobis(2,4-dimethylvaleronitrile) is further added thereto, followed by heating for 2 hours under stirring. Subsequently, the temperature is raised to 100° C., and the mixture is stirred for 2 hours at a reduced pressure of 200 mmHg (about 26.6 kPa) to remove non-reacted monomers. After cooling, the reaction mixture is passed through a 200-mesh nylon cloth to obtain a white dispersion which is a latex of 99% in polymerization ratio and 26.3% in concentration of particles. The volume-average particle size is found to be 1.91 μm by measurement with an ultra-centrifugal automatic particle size distribution analyzer CAPA-700 (manufactured by Horiba, Ltd.).

When the particles are photographed by means of an electron microscope JSM-6700F manufactured by Nihon Denshi Co., the particles are observed to be truly-spherical particles.

The particle image is photographed from the vertical direction with respect to the sample bed, and the thus-obtained image is analyzed by using an image-analyzing program, Mac-View (manufactured by Mountech Co., Ltd.), to find that the average circularity is 0.99.

### Example 3

(Synthesis of a Fine Particles-Containing Dispersion 3)

35 g of glycidyl methacrylate, 10 g of 2-hydroxyethyl methacrylate, 10 g of dimethylaminomethyl methacrylate and 8 g of a dispersion-stabilizing resin (P-1; weight-average molecular weight: 52000) of the above structure are dissolved in 200 g of Isopar G and are heated to 70° C. in a stream of nitrogen, followed by stirring for 1 hour. 0.8 g of 2,2′-azobis(2,4-dimethylvaleronitrile) is added thereto and, after heating for 2 hours under stirring, 0.8 g of 2,2′-azobis(2,4-dimethylvaleronitrile) is further added thereto, followed by heating for 2 hours under stirring. Subsequently, the temperature is raised to 100° C., and the mixture is stirred for 2 hours at a reduced pressure of 200 mmHg (about 26.6 kPa) to remove non-reacted monomers. After cooling, the reaction mixture is passed through a 200-mesh nylon cloth to obtain a white dispersion which is a latex of 98% in polymerization ratio and 19.1% in concentration of particles. The volume-average particle size is found to be 1.65 μm by measurement with an ultra-centrifugal automatic particle size distribution analyzer CAPA-700 (manufactured by Horiba, Ltd.).

When the particles are photographed by means of an electron microscope JSM-6700F manufactured by Nihon Denshi Co., the particles are observed to be non-truly-spherical particles having uneven surface.

The particle image is photographed from the vertical direction with respect to the sample bed, and the thus-obtained image is analyzed by using an image-analyzing program, Mac-View (manufactured by Mountech Co., Ltd.), to find that the average circularity is 0.92.

### Comparative Example 3

(Synthesis of Comparative Fine Particles-Containing Dispersion C)

35 g of methyl acrylate, 10 g of 2-hydroxyethyl methacrylate, 10 g of dimethylaminomethyl methacrylate and 8 g of a dispersion-stabilizing resin (P-1; weight-average molecular weight: 52000) of the above structure are dissolved in 135 g of Isopar G and are heated to 70° C. in a stream of nitrogen, followed by stirring for 1 hour. 0.8 g of 2,2′-azobis(2,4-dimethylvaleronitrile) is added thereto and, after heating for 2 hours under stirring, 0.8 g of 2,2′-azobis(2,4-dimethylvaleronitrile) is further added thereto, followed by heating for 2 hours under stirring. Subsequently, the temperature is raised to 100° C., and the mixture is stirred for 2 hours at a reduced pressure of 200 mmHg (about 26.6 kPa) to remove non-reacted monomers. After cooling, the reaction mixture is passed through a 200-mesh nylon cloth to obtain a white dispersion which is a latex of 99% in polymerization ratio and 18.9% in concentration of particles. The volume-average particle size is found to be 1.77 μm by measurement with an ultra-centrifugal automatic particle size distribution analyzer CAPA-700 (manufactured by Horiba, Ltd.).

When the particles are photographed by means of an electron microscope JSM-6700F manufactured by Nihon Denshi Co., the particles are observed to be truly-spherical particles.

The particle image is photographed from the vertical direction with respect to the sample bed, and the thus-obtained image is analyzed by using an image-analyzing program, Mac-View (manufactured by Mountech Co., Ltd.), to find that the average circularity is 0.99.

### Example 4

(Synthesis of a Fine Particles-Containing Dispersion 4)

35 g of Karenz MOI (trade name; manufactured by Showa Denko K.K.; methacryloyloxyethyl isocyanate), 10 g of 2-hydroxyethyl methacrylate, 10 g of dimethylaminomethyl methacrylate and 8 g of a dispersion-stabilizing resin (P-1; weight-average molecular weight: 52000) of the above structure are dissolved in 200 g of Isopar G and are heated to 70° C. in a stream of nitrogen, followed by stirring for 1 hour. 0.8 g of 2,2′-azobis(2,4-dimethylvaleronitrile) is added thereto and, after heating for 2 hours under stirring, 0.8 g of 2,2′-azobis(2,4-dimethylvaleronitrile) is further added thereto, followed by heating for 2 hours under stirring. Subsequently, the temperature is raised to 100° C., and the mixture is stirred for 2 hours at a reduced pressure of 200 mmHg (about 26.6 kPa) to remove non-reacted monomers. After cooling, the reaction mixture is passed through a 200-mesh nylon cloth to obtain a white dispersion which is a latex of 99% in polymerization ratio and 19.5% in concentration of particles. The volume-average particle size is found to be 1.79 μm by measurement with an ultra-centrifugal automatic particle size distribution analyzer CAPA-700 (manufactured by Horiba, Ltd.).

When the particles are photographed by means of an electron microscope JSM-6700F manufactured by Nihon Denshi Co., the particles are observed to be non-truly-spherical particles having uneven surface.

The particle image is photographed from the vertical direction with respect to the sample bed, and the thus-obtained image is analyzed by using an image-analyzing program, Mac-View (manufactured by Mountech Co., Ltd.), to find that the average circularity is 0.90.

### Example 5

(Synthesis of a Fine Particles-Containing Dispersion 5)

35 g of (Y-1) described below, 10 g of 2-hydroxyethyl methacrylate, 10 g of dimethylaminomethyl methacrylate and 8 g of a dispersion-stabilizing resin (P-1; weight-average molecular weight: 52000) of the above structure are dissolved in 200 g of Isopar G and are heated to 70° C. in a stream of nitrogen, followed by stirring for 1 hour. 0.8 g of 2,2′-azobis(2,4-dimethylvaleronitrile) is added thereto and, after heating for 2 hours under stirring, 0.8 g of 2,2′-azobis(2,4-dimethylvaleronitrile) is further added thereto, followed by heating for 2 hours under stirring. Subsequently, the temperature is raised to 100° C., and the mixture is stirred for 2 hours at a reduced pressure of 200 mmHg (about 26.6 kPa) to remove non-reacted monomers. After cooling, the reaction mixture is passed through a 200-mesh nylon cloth to obtain a white dispersion which is a latex of 99% in polymerization ratio and 19.5% in concentration of particles. The volume-average particle size is found to be 1.65 μm by measurement with an ultra-centrifugal automatic particle size distribution analyzer CAPA-700 (manufactured by Horiba, Ltd.).

When the particles are photographed by means of an electron microscope JSM-6700F manufactured by Nihon Denshi Co., the particles are observed to be non-truly-spherical particles having uneven surface.

The particle image is photographed from the vertical direction with respect to the sample bed, and the thus-obtained image is analyzed by using an image-analyzing program, Mac-View (manufactured by Mountech Co., Ltd.), to find that the average circularity is 0.88. 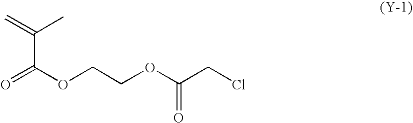
(Synthesis of Colored Dispersions 1 to 5 and Comparative Colored Dispersions A to C)

Each of the above-synthesized fine particles-containing dispersions 1 to 5 and the comparative fine particles-containing dispersions A to C is diluted with Isopar G to adjust the concentration of the particles to 12% by weight. Subsequently, Victoria Pure Blue (manufactured by Hodogaya Chemical Co., Ltd.) is added thereto in an amount of 5% by weight based on the weight of solid components in the dispersion, followed by stirring at 85° C. for 6 hours. After cooling the mixture to room temperature, the mixture is passed through a 200-mesh nylon cloth to obtain colored particles-containing dispersions 1 to 5 and comparative colored particles-containing dispersions A to C.

(Preparation of Ink Compositions)

Next, each of the colored particles-containing dispersions 1 to 5 and the comparative colored particles-containing dispersions A to C is diluted with Isopar G to 7.0% by weight in solid component concentration. Subsequently, an octadecene-maleic acid half octadecylamide copolymer is added thereto as a charge-adjusting agent so that the concentration of the copolymer becomes 0.02% by weight. Thus, ink compositions 1 to 5 and A to C are prepared.

(Evaluation on Ejecting Properties in an Inkjet Device)

An inkjet recording device having the constitution of FIG. 1 is prepared, and the ink composition 1 is fed to the inside of the device. After removing dust on the surface of a recording medium of coated recording paper by air pump suction, the ejecting head is brought to the drawing position near to the coated recording paper, and the ink is ejected with an image-drawing resolution of 600 dpi to draw an image. In this occasion, image drawing is performed with changing the dot area in 16 grades in the range of from 15 μm to 60 μm in dot diameter by applying a pulse voltage of 500 V to the controlling electrode 6. The thus-drawn image is stably printed in uniform dots with no blurring to give a distinct image with satisfactory density and good quality. Stability of ejection from the ink head is also good with causing no clogging and, even after 10-hour continuous image drawing, letters are printed with stable dot shape.

The same procedures are conducted with the ink compositions 2 to 5 and A to C to examine image quality and head clogging. The results are shown in Table 1.

(Evaluation on Mobility)

The mobility is measured by means of a ζ potential-measuring apparatus based on the laser Doppler principle, and is shown in terms of relative mobility taking the mobility of the colored dispersion 1 as 100. Additionally, a larger relative mobility means higher electrophoretic properties of the colored dispersed particles, thus being more preferred. The results are shown in Table 1.

TABLE 1

| Colored | | | | |
|---|---|---|---|---|
| Dispersion | Chargeability | Image Quality | Head Clogging | Mobility |
| 1 | positive charge | good | none | 100 |
| 2 | positive charge | good | none | 120 |
| 3 | positive charge | good | none | 110 |
| 4 | positive charge | good | none | 120 |
| 5 | positive charge | good | none | 130 |
| A | positive charge | thin spots | none | 80 |
| | | being formed | | |
| B | positive charge | thin spots | none | 100 |
| | | being formed | | |
| C | positive charge | thin spots | none | 90 |
| | | being formed | | |

(Preparation of Support)

JIS A 1050 aluminum plates of 0.30 mm in thickness and 1030 mm in width are subjected to the following surface treatment.

(Surface Treatment)

In the surface treatment, the following various treatments (a) to (f) are continuously conducted. Additionally, removal of solution is conducted after each treatment and washing with water.
(a) The aluminum plate is subjected to etching treatment at 70° C. in a solution containing 26% by weight of sodium hydroxide and 6.5% by weight of aluminum ion to dissolve 5 g/m² of the aluminum plate. Thereafter, the aluminum plate is washed with water.
(b) The aluminum plate is subjected to desmutting treatment by spraying a 30° C. aqueous solution of 1% by weight of nitric acid (containing 0.5% by weight of aluminum ion), followed by washing with water.
(C) Electrochemical surface-roughening treatment is conducted by using 60-Hz alternating current voltage. The electrolytic solution is a 30° C. aqueous solution of 1% by weight of nitric acid (containing 0.5% by weight of aluminum ion and 0.007% by weight of ammonium ion). The electrochemical surface-roughening treatment is conducted using a trapezoidal rectangular-wave alternating current of 2 msec in time necessary for the current value to reach from 0 to peak, TP, and 1:1 in duty ratio fed from an alternating current source and using a carbon electrode as an opposed electrode. Ferrite is used for an auxiliary anode. The electric current density at the peak is 25 A/dm², and the amount of electricity is 250 C/cm² in terms of the total amount of electricity while the aluminum plate functions as anode. 5% of the current fed from the power source is fed to the auxiliary anode. Subsequently, the plate is washed with water.
(d) The aluminum plate is subjected to etching treatment at 35° C. by spraying with a sodium hydroxide concentration of 26% by weight and an aluminum ion concentration of 6.5% by weight to thereby dissolve 0.2 g/m² of the aluminum plate. Thus, the smut component mainly comprising aluminum hydroxide having been generated upon foregoing electrochemically coarsening the surface thereof using an alternating current is removed, and edge portions generated are dissolved to smoothen the edge portions. Thereafter, the aluminum plate is washed with water.
(e) Desmutting treatment is conducted by spraying a 60° C. aqueous solution of 25% by weight of sulfuric acid (containing aluminum ion in a concentration of 0.5% by weight), followed by washing with water by spraying.
(f) Anodizing treatment is conducted for 50 seconds in a solution containing 170 g/liter of sulfuric acid (containing aluminum ion in a concentration of 0.5% by weight) at a temperature of 33° C. and an electric current density of 5 (A/dm²), followed by washing with water. The weight of the anodized film is 2.7 g/m².

A solution of the compound UL-1 represented by the following formula (x/y/z/w=20/30/30/20; weight-average molecular weight: 10000) in methanol is coated on the above-prepared support, and then oven-dried at 70° C. for 30 seconds to form an undercoat layer of 15 mg/m² in dry coated weight. 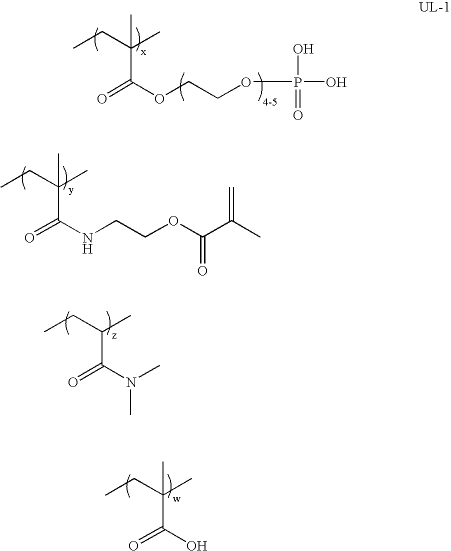
(Preparation of Lithographic Printing Plate)

An inkjet image is formed from the ink composition prepared in each of the Examples on the above-prepared aluminum substrate using the inkjet device and the method described hereinbefore. The ink amount of the image is 1.1 g/m². Thereafter, the image-recorded aluminum plate is dried, and then heated in a 150° C. oven for 10 minutes to fix the ink image on the aluminum support, thus a lithographic printing plate being prepared.

(Evaluation of Printing Performance)

The above-prepared lithographic printing plate is mounted on the cylinder of a printing machine SOR-M manufactured by Heidelberg. Printing is performed at a printing speed of 5,000 sheets per hour using a dampening water (EU-3(an etching solution manufactured by Fuji Photo Film Co., Ltd.)/water/isopropyl alcohol=1/89/10 (by volume)) and a carbon black ink TRANS-G(N) (manufactured by Dainippon Ink & Chemicals, Inc.). As a result, good printed products with no stains in non-image areas are obtained with every ink composition. As the number of printed sheets increases, the image-recording layer is gradually worn away and suffers reduction in ink-receiving properties, and hence the ink density in printed paper decreases. Printing durability is evaluated in terms of the number of printed sheets when the ink density (reflection density) of a solid image area decreases by 0.1 from the initiation of printing. As a result, it is found that 30,000 sheets can be printed.

The present application claims foreign priority based on Japanese Patent Application (JP 2006-157229) filed Jun. 6 of 2006, the contents of which is incorporated herein by reference.

What is claimed is:

1. Non-truly-spherical high-molecular fine particles, which are produced by a radical polymerization between a first radical-polymerizable monomer having a nucleophilic group and a second radical-polymerizable monomer having a group reacting with the nucleophilic group to form a covalent bond in a non-aqueous solvent in the presence of a dispersion-stabilizing resin.

2. The Non-truly-spherical high-molecular fine particles as claimed in claim 1, wherein the dispersion-stabilizing resin comprises a polymer soluble in a non-aqueous solvent which polymer has at least a repeating unit represented by the following formula (I): 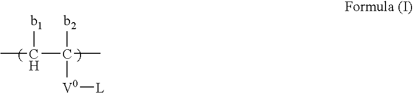
wherein V⁰ represents one of —COO—, —OCO—, —CH₂COO—, —CH₂OCO— and —O—.

3. The Non-truly-spherical high-molecular fine particles as claimed in claim 1, wherein the first radical-polymerizable monomer has a substituent group selected from the group consisting of a radical-polymerizable monomer having a carboxyl group, a primary amino group, a secondary amino group, a phenoxy group, an alkoxy group, a hydroxyl group, a thiol group, a thioalkoxy group, a thiophenoxy group, a —COCHCO— group, a —COCHSO₂— group, a —CONHSO₂— group and a —SO₂NHSO₂— group.

4. The Non-truly-spherical high-molecular fine particles as claimed in claim 1, wherein the second radical-polymerizable monomer has a substituent group selected from the group consisting of an epoxy group, an isocyanato group, a thioisocyanato group, an oxetane group, a fluoroalkyl group, a chloroalkyl group, a bromoalkyl group, an iodoalkyl group, a sulfonic acid group, a trifluoromethanesulfonic acid alkyl group, a perfluoroalkanesulfonic acid alkyl group such as pentafluoroethanesulfonic acid alkyl group, tosylic acid alkyl group and a perfluoroalkanecarboxylic acid alkyl group.

5. The Non-truly-spherical high-molecular fine particles as claimed in claim 1, wherein the first and second radical-polymerizable monomers comprise a cationic monomer having a cationic group selected from the group consisting of at least one amino group represented by the general formula (II) within the molecule and polymerizable monomers having a nitrogen-containing hetero ring. 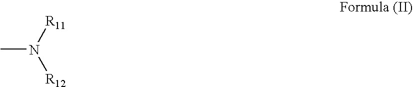
wherein R₁₁ and R₁₂, which is the same or different, each represents one of a hydrogen atom and a hydrocarbon group containing from 1 to 22 carbon atoms. R₁₁ and R₁₂ are connected to each other to form a ring.

6. The Non-truly-spherical high-molecular fine particles as claimed in claim 5, wherein the cationic monomer is mixed with the first and second radical-polymerizable monomers in a proportion of from 1 to 50% by weight based on the total weight of the first and second radical-polymerizable monomers and the cationic monomer.

7. The Non-truly-spherical high-molecular fine particles as claimed in claim 1, which have a molar ratio of the first radical-polymerizable monomer to the second radical-polymerizable monomer being from 9:1 to 1:9.

8. The Non-truly-spherical high-molecular fine particles as claimed in claim 1, which have an average particle size being from 0.05 to 10 μm.

9. The Non-truly-spherical high-molecular fine particles as claimed in claim 1, wherein the dispersion-stabilizing resin has an amount being from 3 to 40 parts by weight per 100 parts by weight of total monomers.

10. A process for producing non-truly-spherical high-molecular fine particles, which comprise:
dissolving, in a non-aqueous solvent, a dispersion-stabilizing resin, a first radical-polymerizable monomer having a nucleophilic group and a second radical-polymerizable monomer having a group capable of reacting with the nucleophilic group to form a covalent bond so as to form resin particles;
adding thereto a radical polymerization initiator; and
heating the mixture to conduct radical polymerization reaction.

11. The process for producing non-truly-spherical high-molecular fine particles as claimed in claim 10, wherein the non-truly-spherical high-molecular fine particles has a weight ratio of the resin particles to total weight of the first and second radical-polymerizable monomers is from 5:95 to 95:5.

12. An inkjet ink composition, which comprises the non-truly-spherical high-molecular fine particles according to claim 1.

13. A process for producing a lithographic printing plate, which comprises:
ejecting the inkjet ink according to claim 13 to deposit onto a hydrophilic support; and
curing the deposited inkjet ink composition by irradiation with radiation to form a hydrophobic region.

14. A lithographic printing plate, which is produced by the process for producing a lithographic printing plate according to claim 13.

15. An electrophoretic particles-containing composition, which comprises:
non-truly-spherical high-molecular fine particles according to claim 1;
a non-aqueous solvent; and
a charge-adjusting agent.
